(19) United States
(12) Patent Application Publication
(10) Pub. No.: US 2007/0049760 A1
(43) Pub. Date: Mar. 1, 2007

(54) Carbazole derivative, material for light emitting element, light emitting element, light emitting device, and electronic device

(75) Inventors: Sachiko Kawakami, Isehara (JP); Nobuharu Ohsawa, Zama (JP); Harue Nakashima, Atsugi (JP); Kumi Kojima, Machida (JP); Satoshi Seo, Kawasaki (JP); Masakazu Egawa, Isehara (JP); Ryoji Nomura, Yamato (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., Atsugi-shi (JP)

(21) Appl. No.: 11/511,467

(22) Filed: Aug. 29, 2006

(30) Foreign Application Priority Data
Aug. 31, 2005 (JP) 2005-252308

(51) Int. Cl. H01L 51/54; C09K 11/06

(52) U.S. Cl. 548/440; 548/442; 428/690; 428/917; 313/504; 313/506; 257/E51.049; 257/E51.05; 257/E51.051; 257/40

(57) ABSTRACT

An object of the present invention is to provide a carbazole derivative which is useful in manufacturing a substance having resistance to oxidation. Another object is to provide a carbazole derivative which is useful in manufacturing a novel material with high reliability. Still another object is to provide a material for a light emitting element with high reliability. The present invention is a carbazole derivative represented by the following general formula (1) (where each of Ar¹ and Ar² represents an aryl group having 6 to 14 carbon atoms which may include a substitute, Ar¹ and Ar² may be either the same or different, and R in the formula represents hydrogen or an alkyl group having 1 to 4 carbon atoms). In addition, the present invention is a material for a light emitting element which includes a carbazole derivative represented by the following general formula (1) as a substituent.

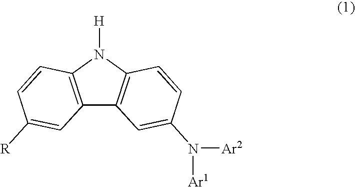

### TECHNICAL FIELD

The present invention relates to a light emitting material. In addition, the present invention relates to a light emitting element including a pair of electrodes and a layer containing a light emitting material which can provide light emission when an electric field is applied. Further, the present invention relates to a light emitting device including such a light emitting element.

### BACKGROUND ART

A light emitting element using a light emitting material has features such as thinness, lightness, high-speed response, and DC drive at low voltage, which is expected to be applied to a next-generation flat panel display. In addition, a light emitting device in which light emitting elements are arranged in matrix has a viewing angle wider than that of a conventional liquid crystal display device; therefore, it has excellent visibility.

A light emitting mechanism of the light emitting element is described. When a voltage is applied to a light emitting layer interposed between a pair of electrodes, electrons injected from a cathode and holes injected from an anode are recombined with each other at a light emitting center of the light emitting layer, thereby forming molecular excitons. Then, the molecular exciton releases light energy when returning to a ground state, so that light emission is caused. Singlet excitation and triplet excitation are known as excited states, and it is thought that light emission can be achieved through either of the excited states.

A light emitting material included in the light emitting layer or a host material for dispersing the light emitting material is repeatedly oxidized by holes and reduced by electrons (which is hereinafter referred to as an “oxidation-reduction cycle”). Thus, a material having high resistance to the oxidation and reduction is highly reliable when used as a light emitting material.

An emission wavelength of a light emitting element is determined by a band gap of a light emitting molecule contained in the light emitting element. Accordingly, light emitting elements with various emission colors can be obtained by devising structures of the light emitting molecules. In addition, a full-color light emitting device can be manufactured by using respective light emitting elements which can emit light of red, blue, and green, which are three primary colors of light.

Meanwhile, many factors in addition to color purity are required for the light emitting device. In particular, it can be said that high reliability is an essential factor for the light emitting device. However, it is very difficult to realize a light emitting element with excellent color purity and high reliability. Therefore, research has been actively made in order to obtain a light emitting material which can satisfy both reliability and required color purity (for example, see Reference 1: Japanese Patent Laid-Open No. 2003-31371).

### DISCLOSURE OF INVENTION

It is an object of the present invention to provide a carbazole derivative which is useful in manufacturing a substance having resistance to oxidation.

It is another object of the present invention to provide a carbazole derivative which is useful in manufacturing a novel material with high reliability.

It is still another object of the present invention to provide a material for a light emitting element with high reliability.

It is yet another object of the present invention to provide a light emitting element and a light emitting device with high reliability.

The present invention is a carbazole derivative represented by the following general formula (1).

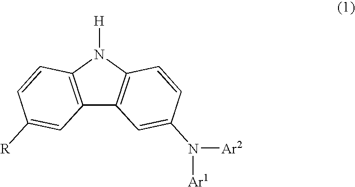

(Note that each of Ar¹ and Ar² in the formula represents an aryl group having 6 to 14 carbon atoms which may include a substituent, and Ar¹ and Ar² may be either the same or different. In addition, R in the formula represents hydrogen or an alkyl group having 1 to 4 carbon atoms.)

The present invention is a carbazole derivative represented by the following structural formula (2).

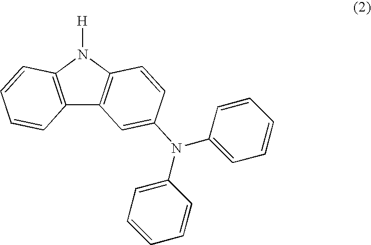

The present invention is a material for a light emitting element, into which a carbazole site represented by the following general formula (3) is introduced as a substituent.

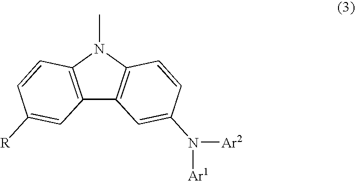

(Note that each of Ar¹ and Ar² in the formula represents an aryl group having 6 to 14 carbon atoms which may include a substituent, and Ar¹ and Ar² may be either the same or different. In addition, R in the formula represents hydrogen or an alkyl group having 1 to 4 carbon atoms.)

The present invention is a material for a light emitting element, into which a carbazole site represented by the following structural formula (4) is introduced as a substituent.

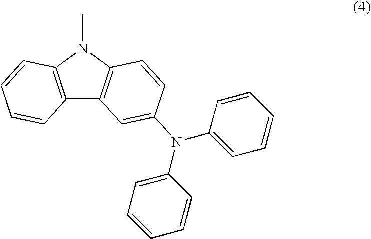

The present invention is a material for a light emitting element, which is represented by the following general formula (5).

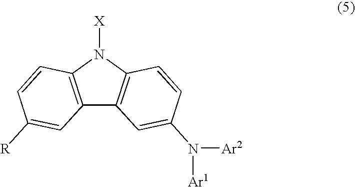

(Note that each of Ar¹ and Ar² in the formula represents an aryl group having 6 to 14 carbon atoms which may include a substituent, and Ar¹ and Ar² may be either the same or different. In addition, R in the formula represents hydrogen or an alkyl group having 1 to 4 carbon atoms, and X represents a light emitting unit.)

The present invention is a material for a light emitting element, which is represented by the following general formula (6).

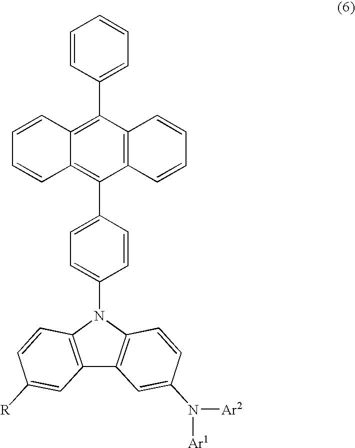

(Note that each of Ar¹ and Ar² in the formula represents an aryl group having 6 to 14 carbon atoms which may include a substituent, and Ar¹ and Ar² may be either the same or different. R in the formula represents hydrogen or an alkyl group having 1 to 4 carbon atoms.

The present invention is a light emitting element containing the above-described material for a light emitting element.

The present invention is a light emitting device including the above-described light emitting element and a control circuit which controls light emission of the light emitting element.

The present invention is an electronic device including a display portion having the above-described light emitting element and a control means of the light emitting element.

By introducing the carbazole derivative of the present invention into a compound as a substituent, a compound having high resistance to an oxidation-reduction cycle can be manufactured. In addition, electrochemical stability of the compound can be improved. Further, a compound with high reliability as a material for a light emitting element can be produced.

The material for a light emitting element of the present invention is a material for a light emitting element having high resistance to an oxidation-reduction cycle. In addition, it is a material for a light emitting element with high electrochemical stability. Further, it is a material for a light emitting element with high reliability.

Moreover, the light emitting device of the present invention containing a material for a light emitting element into which the above-described carbazole derivative is introduced as a substituent is a light emitting device with high reliability.

### BRIEF DESCRIPTION OF DRAWINGS

FIG. 1 is a diagram showing a light emitting element of the present invention.

FIGS. 2A to 2E are cross-sectional views for explaining a method for manufacturing an active matrix light emitting device of the present invention.

FIGS. 3A to 3C are cross-sectional views for explaining a method for manufacturing an active matrix light emitting device of the present invention.

FIGS. 4A and 4B are cross-sectional views of an active matrix light emitting device of the present invention.

FIGS. 5A and 5B are a top view and a cross-sectional view of a light emitting device of the present invention, respectively.

FIGS. 6A to 6F are diagrams showing examples of pixel circuits of a light emitting device of the present invention.

FIG. 7 is a diagram showing an example of a protective circuit of a light emitting device of the present invention.

FIGS. 8A and 8B are a top view and a cross-sectional view of a passive matrix light emitting device of the present invention, respectively.

FIGS. 9A to 9E are diagrams showing examples of electronic devices to which the present invention can be applied.

FIG. 10 shows a ¹H NMR spectrum of 3-(N,N-diphenyl)aminocarbazole.

FIG. 11 shows a ¹H NMR spectrum of CzA1PA.

FIG. 12 shows emission spectra of a thin film of CzA1PA and CzA1PA in toluene.

FIGS. 13A and 13B are CV charts on a reduction side and an oxidation side of CzA1PA, respectively.

FIGS. 14A and 14B are CV charts on a reduction side and an oxidation side of DPAnth, respectively.

FIG. 15 shows a ¹H NMR spectrum of CzPA.

### BEST MODE FOR CARRYING OUT THE INVENTION

Hereinafter, Embodiments of the present invention are explained in detail with reference to the accompanying drawings. However, the present invention is not limited to the following explanation. As is easily known to a person skilled in the art, the mode and the detail of the invention can be variously changed without departing from the spirit and the scope of the present invention. Therefore, the present invention is not interpreted as being limited to the following description of the Embodiments.

### Embodiment 1

This Embodiment explains a carbazole derivative of the present invention. The carbazole derivative of the present invention is represented by the following general formula (1).

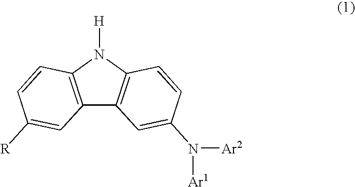

Note that each of Ar¹ and Ar² in the formula represents a substituent having 6 to 14 carbon atoms, and Ar¹ and Ar² may be either the same or different. The substituent having 6 to 14 carbon atoms is preferably an aryl group such as a phenyl group, a naphthyl group, a biphenyl group, an anthryl group, or a phenanthryl group. In addition, R in the formula represents hydrogen or an alkyl group having 1 to 4 carbon atoms. The alkyl group having 1 to 4 carbon atoms is preferably a methyl group or t-butyl group. Note that each of Ar¹ and Ar² may include a substituent. The substituent is preferably an alkyl group having 1 to 4 carbon atoms. Specifically, the substituent is preferably a methyl group or a t-butyl group.

Typical examples of the carbazole derivative of the present invention represented by the above general formula (1) are shown in the following structural formulas (2), (7) to (32). It is needless to say that the present invention is not limited thereto.

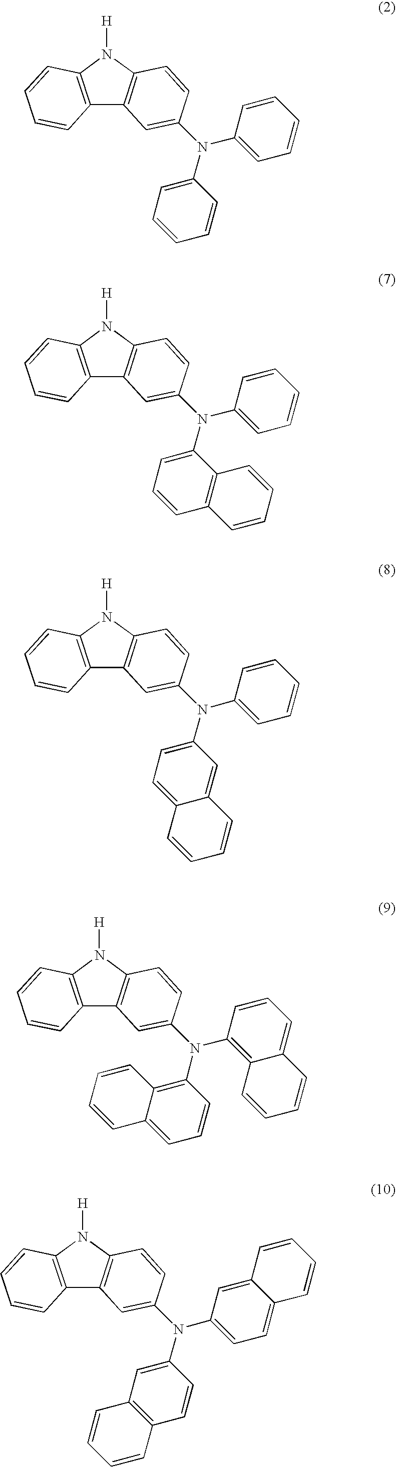

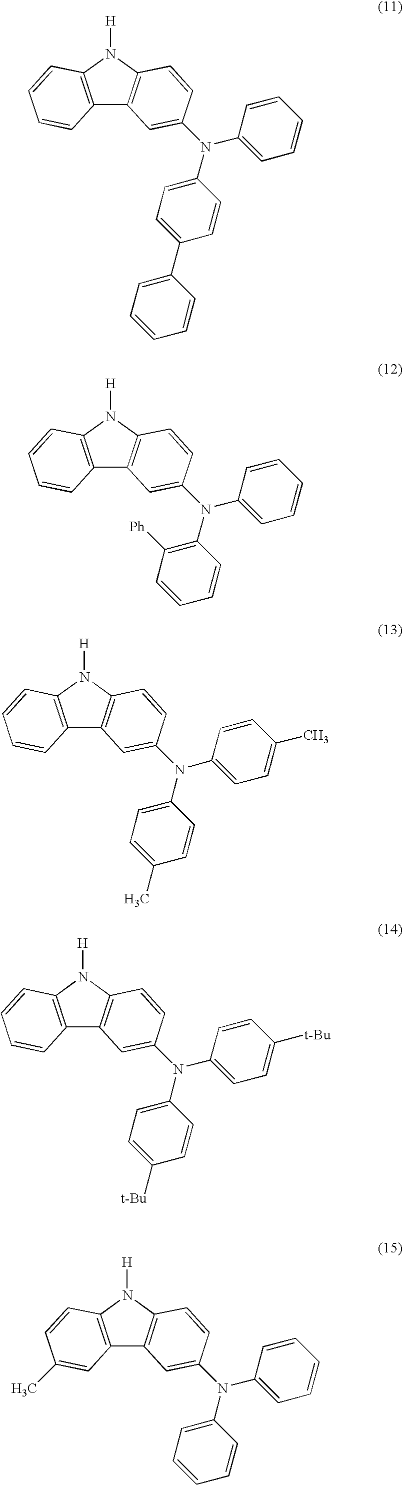

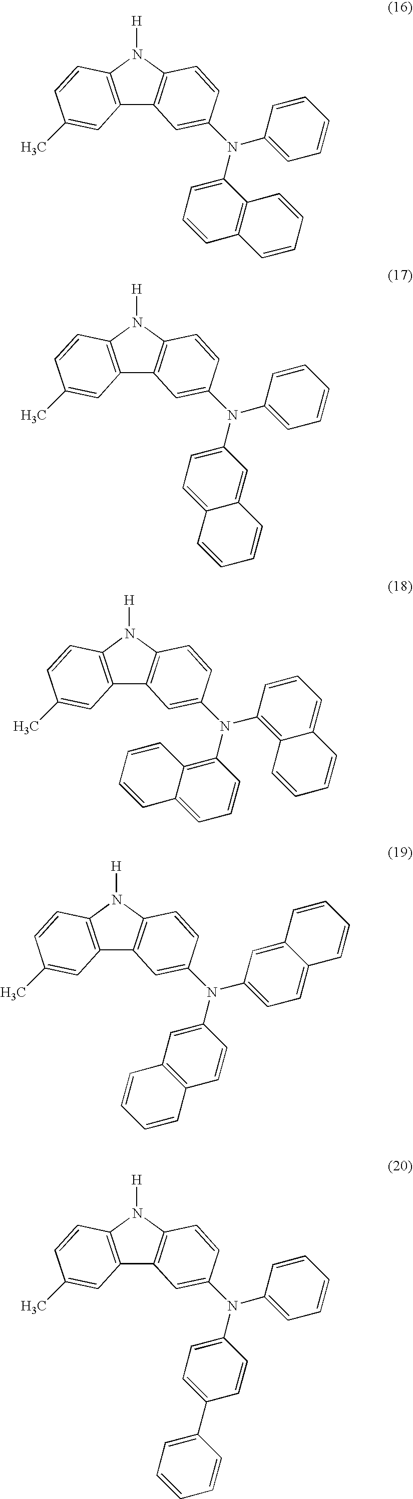

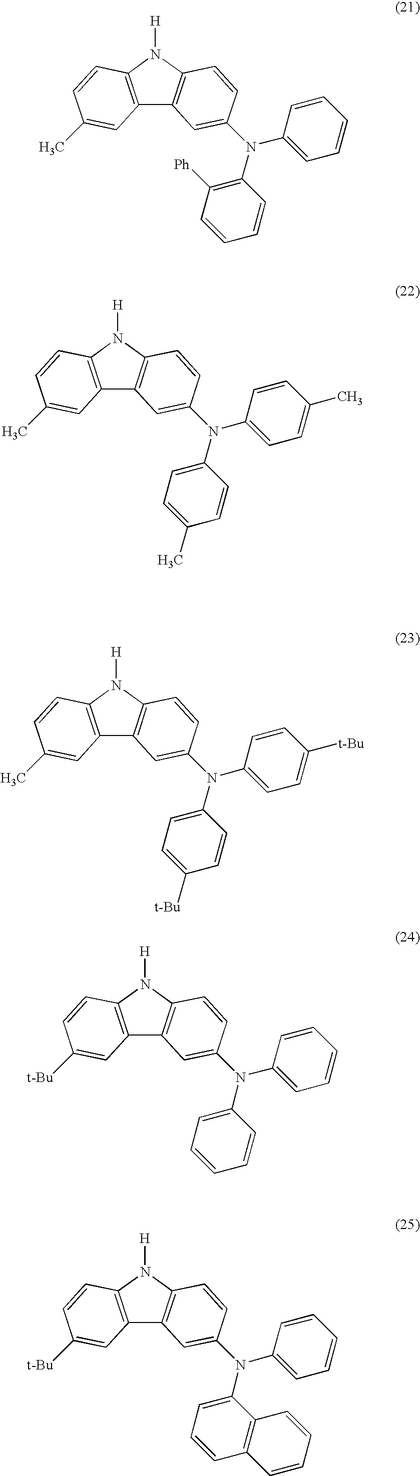

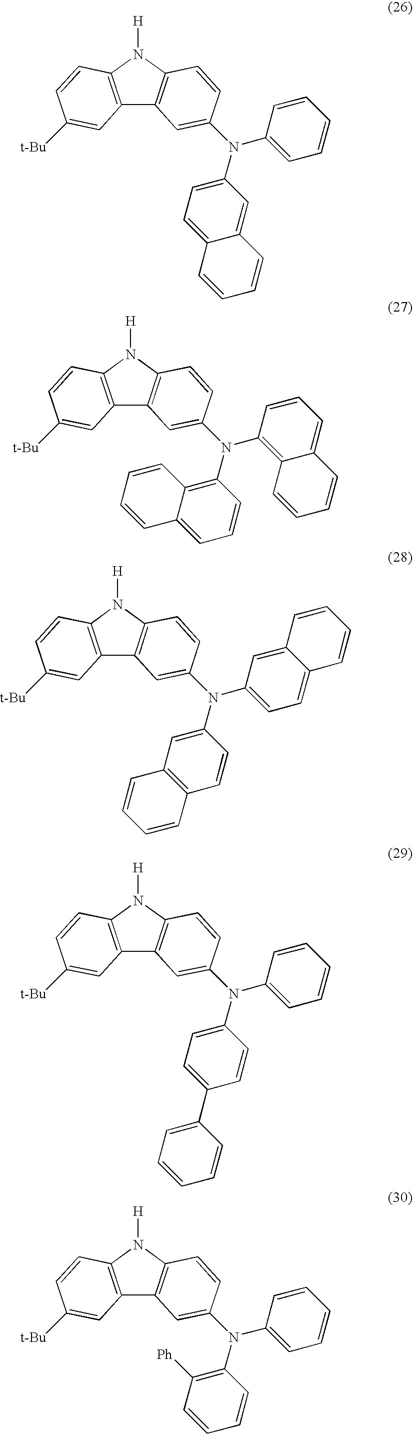

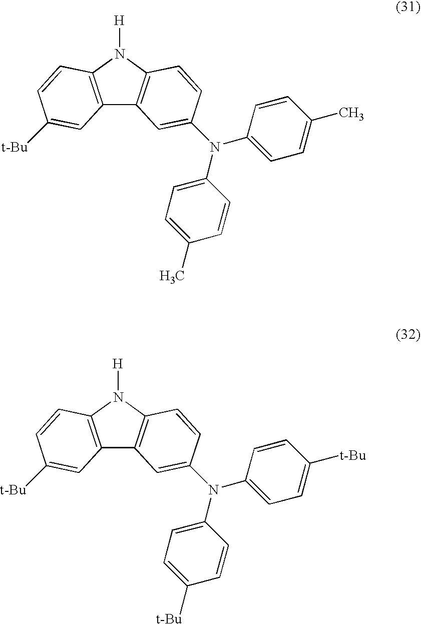

A compound into which the carbazole derivative of the present invention having the above structure is introduced as a substituent (substitution position is at 9-position of a 9H carbazole skeleton) is easily oxidized. The oxidized compound can reversibly return to an original neutral molecule. Therefore, electrochemical stability of a compound into which the carbazole derivative of the present invention is introduced is improved. This improves reliability, as a material for a light emitting element, of the compound into which the carbazole derivative of the present invention is introduced. In addition, reliability of a light emitting element using the compound into which the carbazole derivative of the present invention is introduced is improved. When the light emitting element is used for a light emitting device or an electronic device, reliability of the light emitting device or the electronic device can be improved.

In an organic light emitting element, layers having functions other than a light emitting function (for example, layers from a layer formed of a hole transporting material to a layer formed of an electron transporting material, which are hereinafter referred to as “functional layers”) are often provided in contact with a light emitting layer in order to improve light emission efficiency. In addition, the position of a light emitting region in the light emitting layer is preferably fixed. The light emitting region is preferably fixed in a position close to one of the functional layers in contact with the light emitting layer (for example, a functional layer on a side close to the layer formed of a hole transporting material or a functional layer on a side close to the layer formed of an electron transporting material). Here, when a band gap of the functional layer is small (in other words, when an emission wavelength thereof is longer than that of the light emitting layer), a part or all of excitation energy of a light emitting material formed in the light emitting layer may be transferred to the functional layer. In this case, light emission from the light emitting layer cannot be obtained in some cases. Alternatively, the functional layer emits light due to excitation energy transfer; therefore, light emission from the light emitting layer and light emission from the functional layer may be mixed. In the latter case, deterioration of color purity, decrease in light emission efficiency of the light emitting element, and the like are caused.

As examples of the functional layer, carrier transport layers formed of a hole transporting material, an electron transporting material, and the like can be given. There are many hole transporting materials with large band gaps and short light emission wavelengths. In addition, there are many hole transporting materials which exhibit excellent reliability even when applied to a light emitting element. In contrast, although there are some electron transporting materials with high reliability, many of them generally have small band gaps. Accordingly, in the case of manufacturing a light emitting element which exhibits light emission in a short wavelength range, long-wavelength light tends to be emitted when a light emitting region is positioned in a region close to an electron transporting region. In order to obtain emission of short-wavelength light, a light emitting region is preferably positioned in a region close to a hole transporting region.

To achieve this, an optimal structure of the light emitting layer is that a light emitting material which has a hole transporting property and can trap holes is added to a host material which has an electron transporting property. In this regard, a compound into which the carbazole derivative of the present invention is introduced as a substituent can trap holes efficiently. Therefore, when the compound into which the carbazole derivative of the present invention is introduced as a substituent is used as a material of the light emitting layer, the light emitting region can be positioned on the hole transporting layer side. Thus, deterioration of color purity of the light emitting element is hardly caused. In addition, since the compound can trap holes efficiently, recombination efficiency of holes and electrons can be improved. Therefore, the carbazole derivative of the present invention contributes also to improvement of light emission efficiency.

### Embodiment 2

This Embodiment explains a material for a light emitting element of the present invention. The material for a light emitting element of the present invention is a compound into which the carbazole derivative described in Embodiment 1 is introduced as a substituent.

Typical examples of the compounds of the present invention are shown in the following structural formulas (33) to (61).

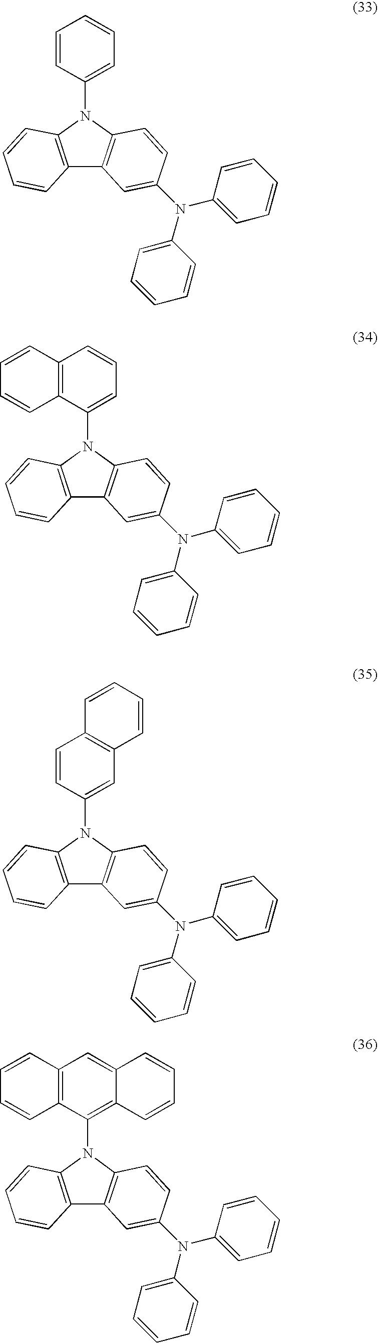

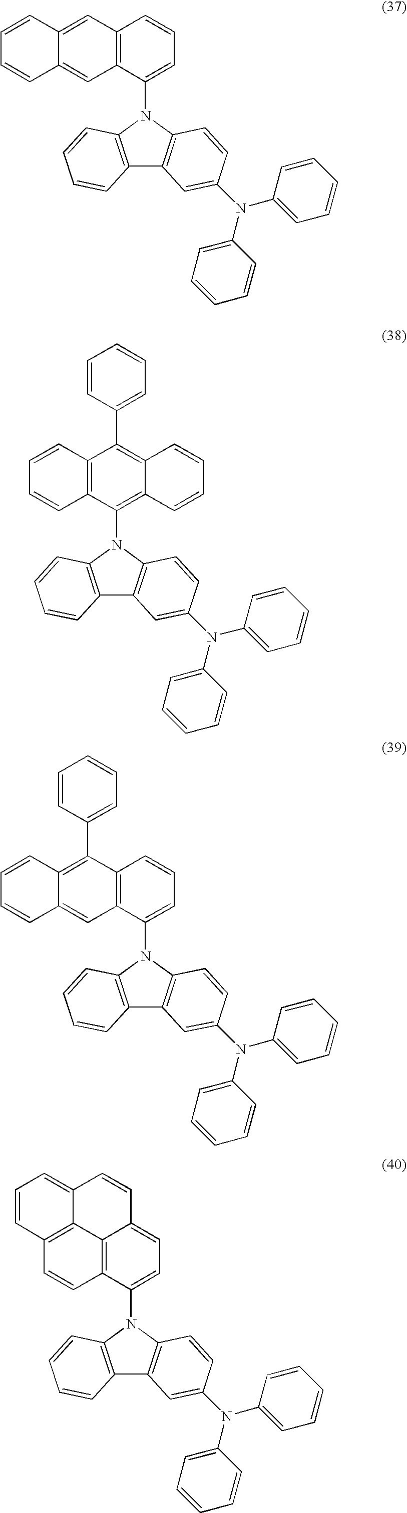

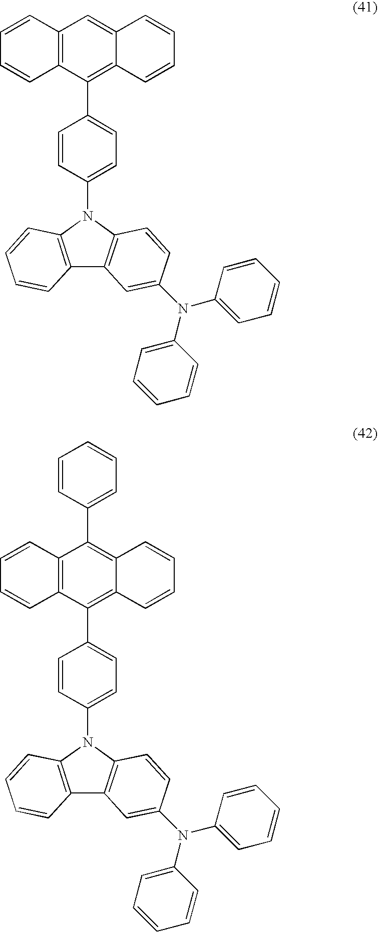

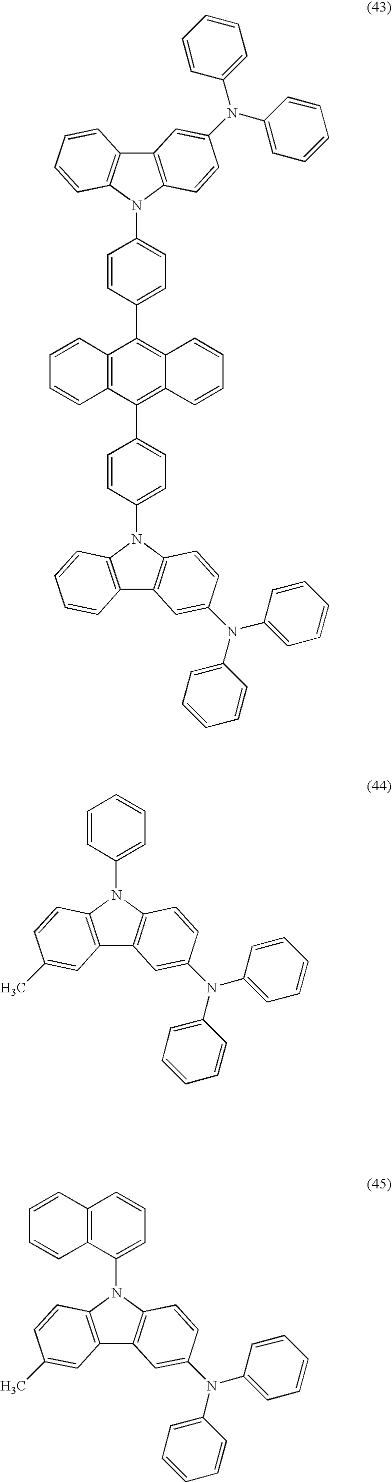

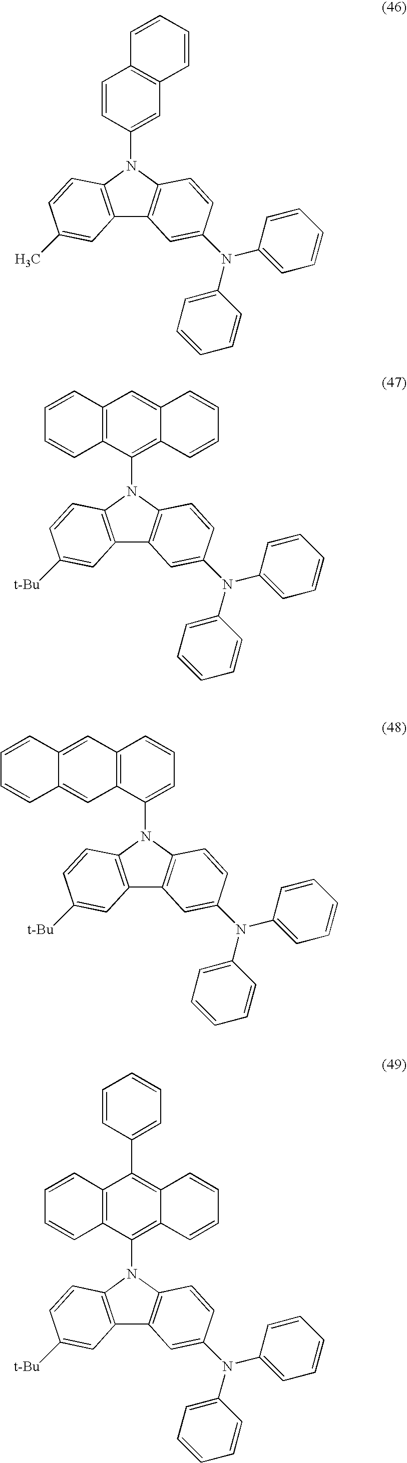

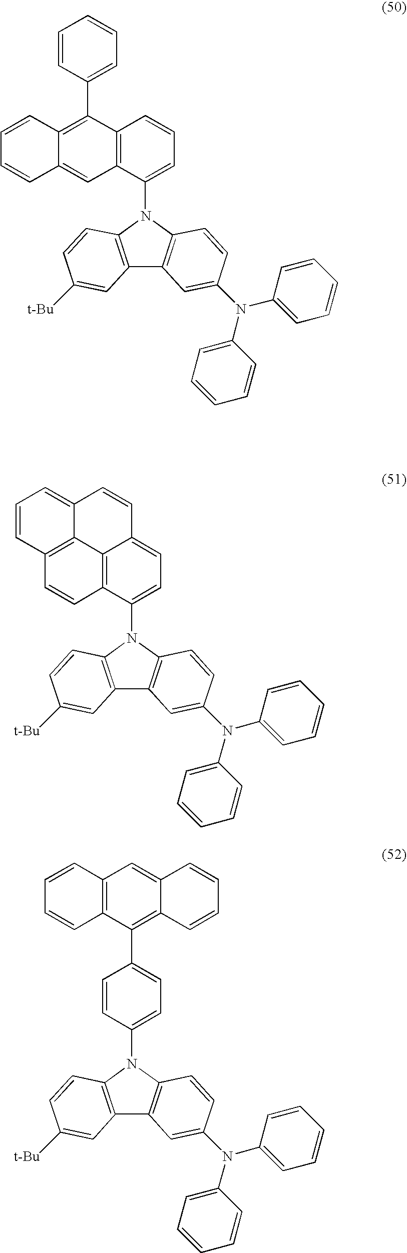

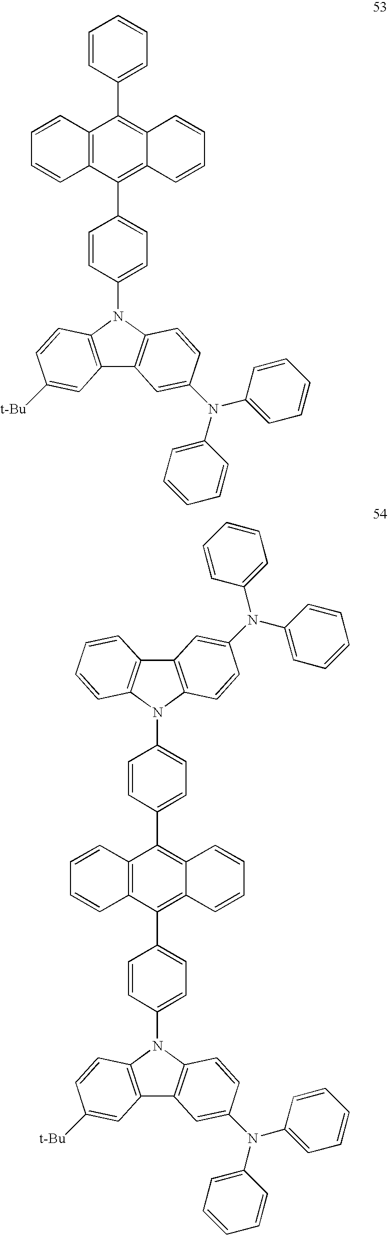

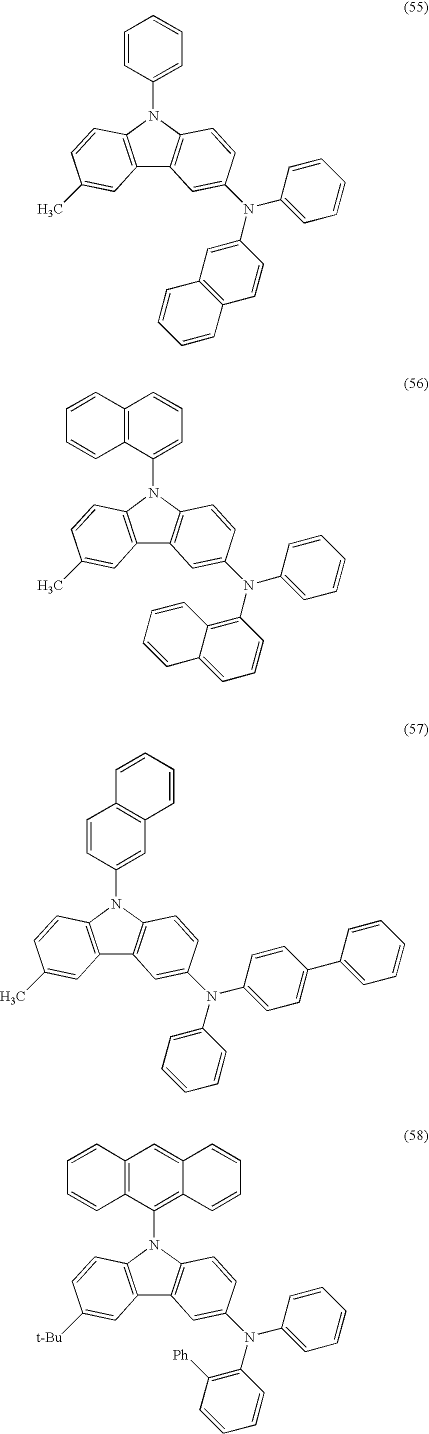

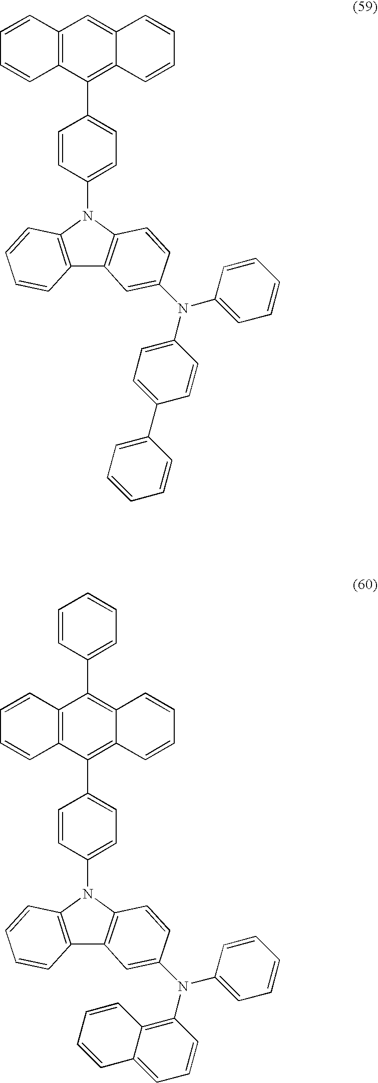

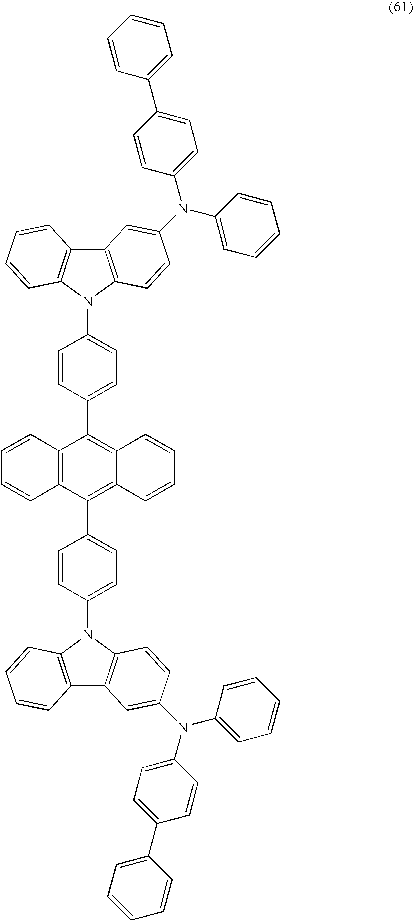

The material for a light emitting element of the present invention having the above structure is easily oxidized. The oxidized material for a light emitting element can reversibly return to an original neutral molecule. Therefore, electrochemical stability of the material for a light emitting element of the present invention is improved. This improves reliability, as a material for a light emitting element, of the compound into which the carbazole derivative of the present invention is introduced. In addition, reliability of a light emitting element using the material for a light emitting element of the present invention is improved. When the light emitting element is used for a light emitting device or an electronic device, reliability of the light emitting device or the electronic device can be improved.

In an organic light emitting element, layers having functions other than a light emitting function (for example, layers from a layer formed of a hole transporting material to a layer formed of an electron transporting material, which are hereinafter referred to as “functional layers”) are often provided in contact with a light emitting layer in order to improve light emission efficiency. In addition, the position of a light emitting region in the light emitting layer is preferably fixed. The light emitting region is preferably fixed in a position close to either of the functional layers in contact with the light emitting layer (for example, a functional layer on a side close to the layer formed of a hole transporting material or a functional layer on a side close to the layer formed of an electron transporting material). Here, when a band gap of the functional layer is small (in other words, when an emission wavelength thereof is longer than that of the light emitting layer), a part or all of excitation energy of a light emitting material formed in the light emitting layer may be transferred to the functional layer. In this case, light emission from the light emitting layer cannot be obtained in some cases. Alternatively, the functional layer emits light due to excitation energy transfer; therefore, light emission from the light emitting layer and light emission from the functional layer may be mixed. In the latter case, deterioration of color purity, decrease in light emission efficiency of the light emitting element, and the like are caused.

As examples of the functional layers, carrier transport layers formed of a hole transporting material, an electron transporting material, and the like can be given. There are many hole transporting materials with large band gaps and short light emission wavelengths. In addition, there are many hole transporting materials which exhibit excellent reliability even when applied to a light emitting element. In contrast, although there are some electron transporting materials with high reliability, many of them generally have small band gaps. Accordingly, in the case of manufacturing a light emitting element which exhibits light emission in a short wavelength range, long-wavelength light tends to be emitted when a light emission region is positioned in a region close to an electron transporting region. In order to obtain emission of short-wavelength light, a light emitting region is preferably positioned in a region close to a hole transporting region.

To achieve this, an optimal structure of the light emitting layer is that a light emitting material that has a hole transporting property and can trap holes is added to a host material having an electron transporting property. In this regard, the material for a light emitting element of the present invention can trap holes efficiently. Therefore, when the material for a light emitting element of the present invention is used as a material of the light emitting layer, the light emitting region can be positioned on the hole transporting layer side. Thus, deterioration of color purity of the light emitting element is hardly caused. In addition, since the material for a light emitting element/compound can trap holes efficiently, recombination efficiency of holes with electrons can be improved. Therefore, the material for a light emitting element of the present invention contributes also to improvement of light emission efficiency.

The light emitting material in the light emitting layer is preferably a material for a light emitting element having a structure as represented by the following general formula (5). X in the formula is a light emitting unit having a light emitting function. The light emitting unit refers to a skeleton which can be used as a light emitting material without a substituent. In particular, a material for a light emitting element which uses 9,10-diphenylanthracene as a light emitting unit (a material represented by the following general formula (6)) exhibits favorable blue light emission and has high reliability and light emission efficiency.

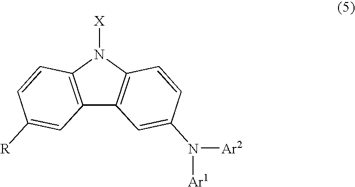

(Note that each of Ar¹ and Ar² in the formula represents an aryl group having 6 to 14 carbon atoms which may include a substituent, and Ar¹ and Ar² may be either the same or different. In addition, R in the formula represents hydrogen or an alkyl group having 1 to 4 carbon atoms, and X represents a light emitting unit.)

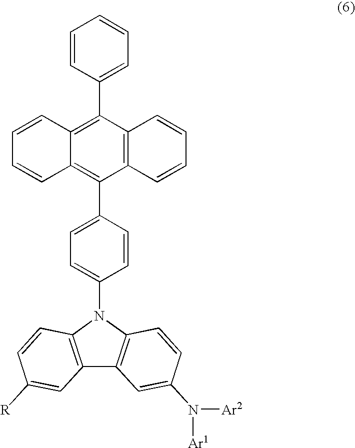

### Embodiment 3

This Embodiment explains a light emitting element using a compound into which the carbazole derivative described in Embodiment 1 is introduced as a substituent.

A light emitting element of the present invention has a structure in which a layer containing a light emitting substance is interposed between a pair of electrodes. Note that there is no particular limitation on an element structure, and a known structure can be appropriately selected for the purpose.

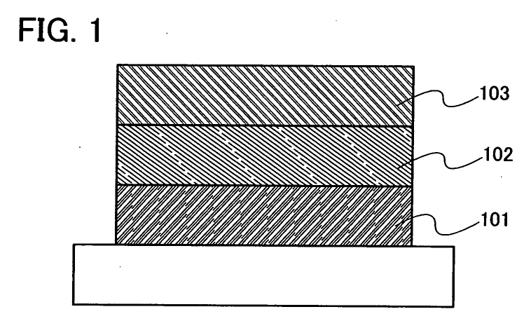

FIG. 1 shows an example of an element structure of the light emitting element of the present invention. The light emitting element shown in FIG. 1 has a structure in which a layer 102 containing a light emitting substance is interposed between a first electrode 101 and a second electrode 103. The layer 102 containing a light emitting substance contains a compound into which the carbazole derivative described in Embodiment 1 is introduced as a substituent. Note that an anode in the present invention means an electrode which injects holes into a layer containing a light emitting material. On the other hand, a cathode in the present invention means an electrode which injects electrons into a layer containing a light emitting material. One of the first electrode 101 and the second electrode 103 is an anode, and the other is a cathode.

For the anode, a known material can be used, and metal, an alloy, a conductive compound, a mixture thereof, or the like having a high work function (specifically, 4.0 eV or higher) is preferably used. Specifically, indium tin oxide (hereinafter referred to as ITO), indium tin oxide containing silicon, indium oxide containing zinc oxide (ZnO) of 2 wt % to 20 wt %, or the like can be used. These conductive metal oxide films are generally formed by a sputtering method, but may be formed by a sol-gel method or the like. Alternatively, gold (Au), platinum (Pt), nickel (Ni), tungsten (W), chromium (Cr), molybdenum (Mo), iron (Fe), cobalt (Co), copper (Cu), palladium (Pd), nitride of a metal material (for example, titanium nitride (TiN)), or the like can be used.

On the other hand, for the cathode, a known material can be used, and metal, an alloy, a conductive compound, a mixture thereof, or the like having a low work function (specifically, 3.8 eV or lower) can be used. Specifically, metal belonging to Group 1 or 2 of the periodic table, for example, alkali metal such as lithium (Li) or cesium (Cs); alkaline earth metal such as magnesium (Mg), calcium (Ca), or strontium (Sr); an alloy containing these (an alloy of Mg and Ag, an alloy of Al and Li, or the like); rare-earth metal such as europium (Er) or ytterbium (Yb); an alloy containing these; or the like can be used. Note that the cathode can also be formed using a material having a high work function, that is, a material generally used for the anode, when using an electron injection layer having a high electron injecting property as the layer 102 containing a light emitting substance. For example, the cathode can be formed of metal such as Al or Ag, or a conductive inorganic compound such as ITO.

The layer 102 containing a light emitting substance can be formed using a known material, and can also be formed using either a low molecular material or a high molecular material. In addition, the material forming the layer 102 containing a light emitting substance is not limited to a material containing only an organic compound material, and it may contain an inorganic compound material in part. In addition, the layer 102 containing a light emitting substance may be formed as a single layer or may be formed by appropriately combining functional layers having respective functions such as a hole injection layer, a hole transport layer, a hole blocking layer, a light emitting layer, an electron transport layer, and an electron injection layer. The above-described functional layers may include a layer having two or more functional layers of the same kind.

In addition, the layer 102 containing a light emitting substance can be formed by either a wet method or a dry method such as an evaporation method, an ink-jet method, a spin coating method, or a dip coating method.

The compound into which the carbazole derivative of the present invention is introduced as a substituent can be used as a material for the light emitting layer or any functional layer of the layer 102 containing a light emitting substance. In particular, it is preferably used as materials for the hole transport layer and the light emitting layer. Accordingly, reliability of a light emitting element can be improved. This is because the compound into which the carbazole derivative of the present invention is introduced as a substituent has high resistance to an oxidation-reduction cycle.

By forming a light emitting layer containing a host material and a compound into which the carbazole derivative of the present invention is introduced as a substituent, efficient light emission can be achieved. This is because the compound into which the carbazole derivative of the present invention is introduced as a substituent traps holes moderately. Furthermore, when the host material is a material having an electron transporting property, a light emitting region of the light emitting layer can be provided on the hole transport layer side (this is because the compound into which the carbazole derivative of the present invention is introduced as a substituent traps holes). Thus, the transfer of excitation energy to the electron transport layer can be suppressed. Consequently, decrease in light emission efficiency, deterioration of color purity of the light emitting element, and the like can be suppressed.

There is no particular limitation on layers other than the layer using the compound into which the carbazole derivative of the present invention is introduced as a substituent. For example, when the compound into which the carbazole derivative of the present invention is introduced as a substituent is used for the hole transport layer, a substance which has favorable light emission efficiency and can emit light with a desired emission wavelength may be used as a light emitting material. For example, in order to obtain red light emission, a substance which exhibits light emission having a peak of an emission spectrum at 600 nm to 680 nm can be used, such as 4-dicyanomethylene-2-isopropyl-6-[2-(1,1,7,7-tetramethyljulolidine-9-yl)ethenyl]-4H-p yran (abbr.: DCJTI), 4-dicyanomethylene-2-methyl-6-[2-(1,1,7,7-tetramethyl-9-julolidine-9-yl)ethenyl]-4H-p yran (abbr.: DCJT), 4-dicyanomethylene-2-tert-butyl-6-[2-(1,1,7,7-tetramethyljulolidine-9-yl)ethenyl]-4H-p yran (abbr.: DCJTB), periflanthene, or 2,5-dicyano-1,4-bis[2-(10-methoxy-1,1,7,7-tetramethyljulolidine-9-yl)ethenyl]benzene. In order to obtain green light emission, a substance which exhibits light emission having a peak of an emission spectrum at 500 nm to 550 nm can be used, such as N,N′-dimethylquinacridon (abbr.: DMQd), coumarin 6, coumarin 545T, or tris(8-quinolinolato)aluminum (abbr.: Alq₃). In order to obtain blue light emission, a substance which exhibits light emission having a peak of an emission spectrum at 420 nm to 500 nm can be used, such as 9,10-bis(2-naphthyl)-tert-butylanthracene (abbr.: t-BuDNA), 9,9′-bianthryl, 9,10-diphenylanthracene (abbr.: DPA), 9,10-bis(2-naphthyl)anthracene (abbr.: DNA), bis(2-methyl-8-quinolinolato)-4-phenylphenolato-gallium (abbr.: BGaq), or bis(2-methyl-8-quinolinolato)-4-phenylphenolato-aluminum (abbr.: BAlq). In addition to the material which generates fluorescence as described above, a material which generates phosphorescence can also be used as a light emitting material, such as bis[2-(3,5-bis(trifluoromethyl)phenyl)pyridinato-N,C^{2′}]iridium(III)picolinate (abbr.: Ir(CF₃ppy)₂(pic)), bis[2-(4,6-difluorophenyl)pyridinato-N,C^{2′}]iridium(III)acetylacetonate (abbr.: FIr(acac)), bis[2-(4,6-difluorophenyl)pyridinato-N,C^{2′}]iridium(III)picolinate (abbr.: FIr(pic)), or tris(2-phenylpyridinato-N,C^{2′})iridium (abbr.: Ir(ppy)₃). In addition, as the host material, an anthracene derivative such as 9,10-di(2-naphthyl)-2-tert-butylanthracene (abbr.: t-BuDNA), a carbazole derivative such as 4,4′-di(N-carbazolyl)biphenyl (abbr.: CBP), a metal complex such as bis[2-(2-hydroxyphenyl)pyridinato]zinc (abbr.: Znpp₂) or bis[2-(2-hydroxyphenyl)benzoxazolato]zinc (abbr.: ZnBOX), or the like can be used. The light emitting layer can be formed by adding a light emitting material to the host material in a proportion of 0.001 wt % to 50 wt %, preferably, 0.03 wt % to 20 wt %. Note that in this case, it is preferable to combine materials so that an energy gap of the host material is larger than that of the light emitting material.

When the compound into which the carbazole derivative of the present invention is introduced as a substituent is used as the host material, a light emitting material of which an energy gap is smaller than that of the compound into which the carbazole derivative of the present invention is introduced as a substituent may be selected from the above-described light emitting materials and may be combined. When the compound into which the carbazole derivative of the present invention is introduced as a substituent is used as a light emitting material, a light emitting material of which a band gap is larger than that of the compound into which the carbazole derivative of the present invention is introduced as a substituent may be selected from the above-described host materials and may be combined. The light emitting layer can be formed by adding the light emitting material to the host material in a proportion of 0.001 wt % to 50 wt % (preferably, 0.03 wt % to 20 wt %) as described above.

As a hole injection material for forming the hole injection layer, a known material can be used. Specifically, metal oxide such as vanadium oxide, molybdenum oxide, ruthenium oxide, or aluminum oxide is preferable. The above oxide may be mixed with an appropriate organic compound. Alternatively, a porphyrin-based compound is effective among organic compounds, and phthalocyanine (abbr.: H₂-Pc), copper phthalocyanine (abbr.: Cu-Pc), or the like can be used. Further, a chemically-doped conductive high molecular compound can be used, such as polyethylene dioxythiophene (abbr.: PEDOT) or polyaniline (abbr.: PAni) doped with polystyrene sulfonate (abbr.: PSS).

As an electron injection material for forming the electron injection layer, a known material can be used. Specifically, alkali metal salt such as lithium fluoride, lithium oxide, or lithium chloride, alkaline earth metal salt such as calcium fluoride, or the like is preferable. Alternatively, a layer in which a donor compound of a material such as lithium is added to a so-called electron transporting material such as tris(8-quinolinolato)aluminum (abbr.: Alq₃) or bathocuproin (abbr.: BCP) can be used.

By using the electron injection layer and the hole injection layer, a carrier injection barrier can be lowered and carriers are efficiently injected into the light emitting element; as a result, a drive voltage can be reduced.

In addition, a carrier transport layer is preferably provided between a carrier injection layer and the light emitting layer. This is because when the carrier injection layer and the light emitting layer are in contact with each other, a part of light emission obtained from the light emitting layer may be quenched (suppressed) and light emission efficiency may be decreased. The hole transport layer is provided between the hole injection layer and the light emitting layer. A preferable material is an aromatic amine-based compound (that is, a compound having a benzene ring-nitrogen bond). A widely-used material is a star-burst aromatic amine compound like 4,4′-bis[N-(3-methylphenyl)-N-phenyl-amino]-biphenyl, or a derivative thereof such as 4,4′-bis[N-(1-naphthyl)-N-phenyl-amino]-biphenyl (hereinafter referred to as NPB), 4,4′,4″-tris(N,N-diphenyl-amino)-triphenylamine, or 4,4′,4″-tris[N-(3-methylphenyl)-N-phenyl-amino]-triphenylamine.

On the other hand, when the electron transport layer is used, it is provided between the light emitting layer and the electron injection layer. An appropriate material is a typical metal complex such as tris(8-quinolinolato)aluminum (abbr.: Alq₃), tris(4-methyl-8-quinolinolato)aluminum (abbr.: Almq₃), bis(10-hydroxybenzo[h]-quinolinato)beryllium (abbr.: BeBq₂), bis(2-methyl-8-quinolinolato)-(4-hydroxy-biphenylyl)-aluminum (abbr.: BAlq), bis[2-(2-hydroxyphenyl)-benzoxazolato]zinc (abbr.: Zn(BOX)₂), or bis[2-(2-hydroxyphenyl)-benzothiazolato]zinc (abbr.: Zn(BTZ)₂). Alternatively, a hydrocarbon-based compound such as 9,10-diphenylanthracene or 4,4′-bis(2,2-diphenylethenyl)biphenyl, or the like is preferable. Moreover, a triazole derivative such as 3-(4-tert-butylphenyl)-4-(4-ethylphenyl)-5-(4-biphenyl)-1,2,4-triazole or a phenanthroline derivative such as bathophenanthroline or bathocuproin may be used.

Note that, although this Embodiment describes a structure of a light emitting element which provides light emission only from the light emitting layer, a light emitting element may be designed so as to provide light emission from another functional layer (such as an electron transport layer or a hole transport layer). For example, light emission can be obtained from a transport layer by adding a dopant to an electron transport layer or a hole transport layer. If emission wavelengths of light emitting materials used for the light emitting layer and the transport layer are different, a spectrum with emission spectra thereof overlapped with each other can be obtained. If emission colors of the light emitting layer and the transport layer have the relationship of complementary colors, white light emission can be obtained.

Note that a variety of light emitting elements can be manufactured by changing the combination of a material for the first electrode 101 and a material for the second electrode 103. When a light transmitting material is used for the first electrode 101, light can be emitted from the first electrode 101 side. When a light blocking (particularly, reflective) material is used for the first electrode 101 and a light transmitting material is used for the second electrode 103, light can be emitted from the second electrode 103 side. Furthermore, when a light transmitting material is used for both the first electrode 101 and the second electrode 103, light can be emitted from both the first electrode 101 side and the second electrode 103 side.

### Embodiment 4

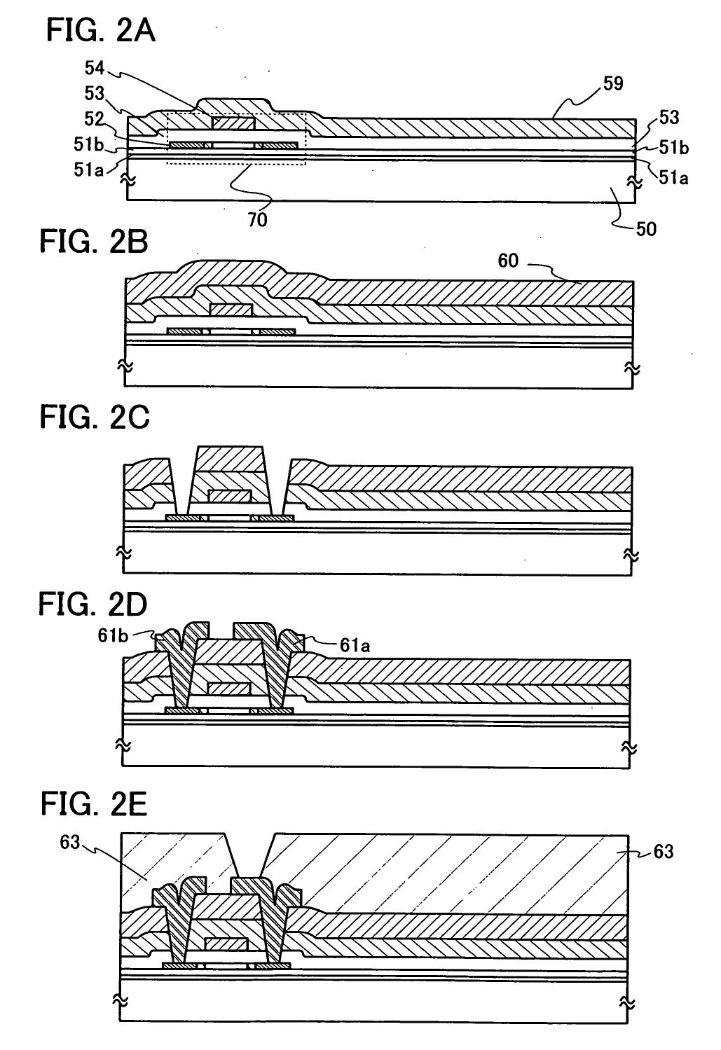

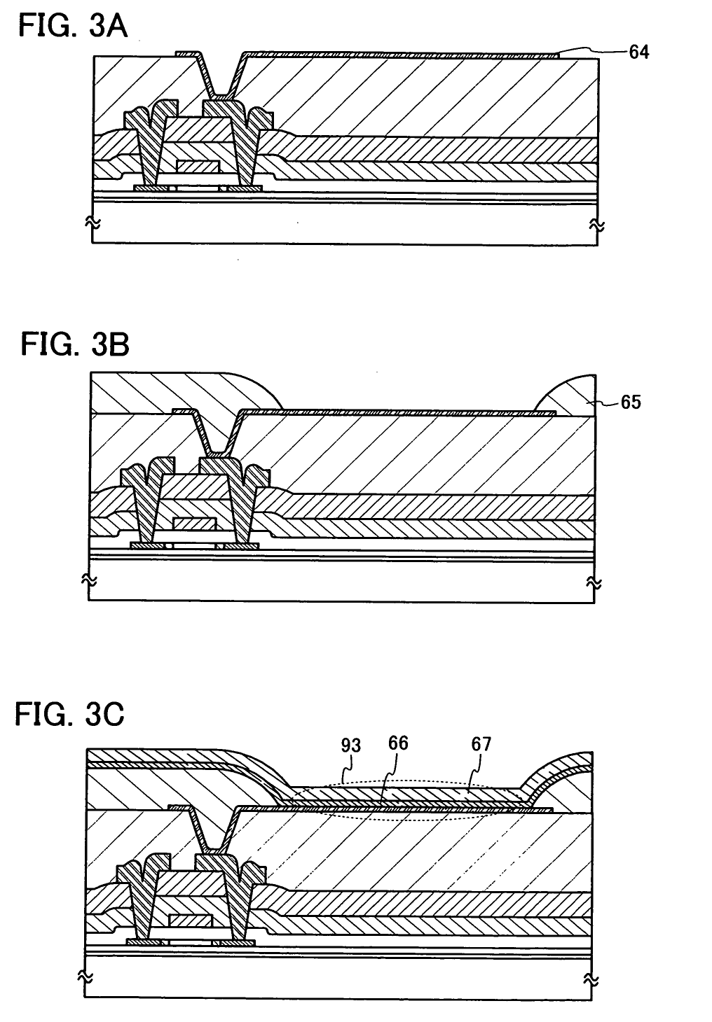

This Embodiment explains a method for manufacturing a light emitting device of the present invention with reference to FIGS. 2A to 3C. Note that, although this Embodiment describes an example of manufacturing an active matrix light emitting device, the present invention can be naturally applied to a passive matrix light emitting device.

First, a first base insulating layer 51a and a second base insulating layer 51b are formed over a first substrate 50. Then, a semiconductor layer is formed over the second base insulating layer 51b (FIG. 2A).

As a material of the first substrate 50, glass, quartz, plastic (such as polyimide, acrylic, polyethylene terephthalate, polycarbonate, polyacrylate, or polyethersulfone), or the like can be used. The first substrate 50 may be used after being polished by CMP or the like if necessary. In this Embodiment, glass is used.

The first base insulating layer 51a and the second base insulating layer 51b are provided to prevent an element which adversely affects the characteristics of the semiconductor layer such as alkali metal or alkaline earth metal in the first substrate 50 from diffusing into the semiconductor layer. As a material of the first base insulating layer 51a and the second base insulating layer 51b, silicon oxide, silicon nitride, silicon oxide containing nitrogen, silicon nitride containing oxygen, or the like can be used. In this Embodiment, silicon nitride is used for the first base insulating layer 51a and silicon oxide is used for the second base insulating layer 51b. The base insulating layer of this Embodiment has a two-layer structure of the first base insulating layer 51a and the second base insulating layer 51b. However, the base insulating layer may have a single-layer structure or a multilayer structure of two or more layers. Note that when the amount of an impurity which diffuses from the substrate is so small as not to affect characteristics of the semiconductor layer, the base insulating layer does not need to be provided.

Next, a semiconductor layer is formed. In this Embodiment, the semiconductor layer is obtained by crystallizing an amorphous silicon film with a laser beam. An amorphous silicon film is formed over the second base insulating layer 51b with a thickness of 25 nm to 100 nm (preferably, 30 nm to 60 nm). As a manufacturing method, a known method such as a sputtering method, a low pressure CVD method, or a plasma CVD method can be used. Then, heat treatment is performed at 500° C. for one hour for dehydrogenation.

Next, the amorphous silicon film is crystallized using a laser irradiation apparatus to form a crystalline silicon film. In the laser crystallization of this Embodiment, an excimer laser is used. An emitted laser beam is processed into a linear beam spot by using an optical system. The crystalline silicon film is formed by irradiating the amorphous silicon film with this linear laser beam and is used as the semiconductor layer.

As the method for crystallizing the amorphous silicon film, another crystallization method is described. For example, there are a crystallization method only by heat treatment, a method using a catalytic element which promotes crystallization and performing heat treatment, and the like. As the element which promotes crystallization, nickel, iron, palladium, tin, lead, cobalt, platinum, copper, gold, or the like can be used. The method using such an element can perform crystallization at a lower temperature and in a shorter time than in the crystallization method only by heat treatment. Therefore, there is less damage to a glass substrate and the like. In the case of using the crystallizing method only by heat treatment, a quartz substrate which is resistant to heat is preferably used as the first substrate 50.

Next, if necessary, a slight amount of an impurity for controlling a threshold value is added to the semiconductor layer (this step is so-called channel doping). In order to obtain a required threshold value, an impurity imparting n-type or p-type conductivity (such as phosphorus or boron) is added by an ion-doping method or the like.

Subsequently, the semiconductor layer is shaped into a desired shape to obtain an island-shaped semiconductor layer 52 as shown in FIG. 2A. The semiconductor layer is shaped as follows. A photoresist is formed over the semiconductor layer, the photoresist is exposed to light to form a predetermined mask shape, and the photoresist is baked. In this manner, a resist mask is formed over the semiconductor layer. Then, the island-shaped semiconductor layer 52 can be formed by etching the semiconductor layer with the use of the resist mask as a mask.

Subsequently, a gate insulating layer 53 is formed to cover the island-shaped semiconductor layer 52. The gate insulating layer 53 is formed by an insulating layer containing silicon with a thickness of 40 nm to 150 nm by a plasma CVD method or a sputtering method. In this Embodiment, the gate insulating layer 53 is formed using silicon oxide.

Then, a gate electrode 54 is formed over the gate insulating layer 53. The gate electrode 54 may be formed of an element selected from tantalum, tungsten, titanium, molybdenum, aluminum, copper, chromium, and niobium, or an alloy or compound material containing the above element as its main component. Alternatively, a semiconductor film doped with an impurity element such as phosphorus, which is typified by a polycrystalline silicon film, may be used. An Ag—Pd—Cu alloy may also be used.

In this Embodiment, the gate electrode 54 is formed of a single layer. However, it may have a stacked structure of two or more layers. For example, there is a stacked structure of two layers using a tungsten layer as a lower layer and a molybdenum layer as an upper layer. When the gate electrode is formed to have a stacked structure, each layer may be formed using the above-described material. A combination of the above materials may also be selected appropriately. The gate electrode 54 is processed by etching with the use of a mask formed of a photoresist.

Next, an impurity is added to the island-shaped semiconductor layer 52 at a high concentration using the gate electrode 54 as a mask. According to this step, a thin film transistor 70 including the island-shaped semiconductor layer 52, the gate insulating layer 53, and the gate electrode 54 is formed.

Note that a manufacturing process for the thin film transistor is not limited in particular and may be modified appropriately so that a transistor having a desired structure can be manufactured.

In this Embodiment, a top-gate thin film transistor using the crystalline silicon film which is crystallized by laser crystallization is used. However, a bottom-gate thin film transistor using an amorphous semiconductor film can be used in a pixel portion. In addition, silicon germanium as well as silicon can be used as an amorphous semiconductor. In the case of using silicon germanium, the concentration of germanium is preferably approximately 0.01 atomic % to 4.5 atomic %.

Next, an impurity element is added to the island-shaped semiconductor layer 52 with the use of the gate electrode 54 as a mask. The impurity element is an element which can impart one conductivity type to the island-shaped semiconductor layer 52. Phosphorus is an example of the impurity element imparting n-type conductivity. Boron or the like is a typical example of the impurity element imparting p-type conductivity. When the first electrode 101 of the light emitting element is formed to function as an anode, an impurity element imparting p-type conductivity is preferably selected. On the other hand, when the first electrode 101 of the light emitting element is formed to function as a cathode, an impurity element imparting n-type conductivity is preferably selected.

Semi-amorphous silicon (also referred to as SAS), which is a semi-amorphous semiconductor, can be obtained by decomposing silane (SiH₄) or the like by glow discharging. Besides silane (SiH₄), for example, Si₂H₆, SiH₂Cl₂, SiHCl₃, SiCl₄, SiF₄, or the like can be used. By using silane (SiH₄) or the like after being diluted with hydrogen, or hydrogen and one or more noble gas elements selected form helium, argon, krypton, and neon, SAS can be easily formed. A dilution ratio of silane (SiH₄) or the like is preferably in the range of 10 times to 1000 times. The reaction to form a film by glow discharge decomposition may be performed under a pressure of 0.1 Pa to 133 Pa. In order to form glow discharge, a high frequency power of 1 MHz to 120 MHz, preferably, 13 MHz to 60 MHz may be supplied. A substrate heating temperature is preferably 300° C. or less, more preferably, 100° C. to 250° C.

The Raman spectrum of the SAS formed in this manner is shifted to a lower wavenumber side than 520 cm⁻¹. In X-ray diffraction, diffraction peaks of a silicon crystal lattice are observed at (111) and (220). Hydrogen or halogen of 1 atomic % or more is included to terminate a dangling bond. As the impurity element in the film, a concentration of an impurity which is an atmospheric constituent such as oxygen, nitrogen, or carbon is preferably 1×10²⁰ cm⁻¹ or less, and particularly, an oxygen concentration is 5×10¹⁹/cm³ or less, preferably, 1×10¹⁹/cm³ or less. A mobility of a TFT manufactured with the SAS is μ=1 cm²/Vsec to 10 cm²/Vsec.

This SAS may be used after being further crystallized by a laser.

Subsequently, an insulating film 59 (hydride film) is formed of silicon nitride to cover the gate electrode 54 and the gate insulating layer 53. By performing heat treatment at 480° C. for approximately one hour after the formation of the insulating film 59 (hydride film), the impurity element is activated and the island-shaped semiconductor layer 52 is hydrogenated.

Next, a first interlayer insulating layer 60 is formed to cover the insulating film 59 (hydride film). As a material for forming the first interlayer insulating layer 60, silicon oxide, acrylic, polyimide, siloxane, a low-k material, or the like is preferably used. In this Embodiment, a silicon oxide film is formed as the first interlayer insulating layer 60 (FIG. 2B).

Next, contact holes that reach the island-shaped semiconductor layer 52 are formed. The contact holes can be formed by etching to expose the island-shaped semiconductor layer 52 with the use of a resist mask. An etching method may be either wet etching or dry etching. Note that etching may be performed once or a plurality of times. When etching is performed a plurality of times, both wet etching and dry etching may be performed (FIG. 2C).

Then, a conductive layer is formed to cover the contact holes and the first interlayer insulating layer 60. The conductive layer is processed into a desired shape, thereby forming a connection portion 61a, a first wire 61b, and the like. This wire may have a single-layer structure of aluminum, copper, an alloy of aluminum, carbon, and nickel, an alloy of aluminum, carbon, and molybdenum, or the like. The wire may have a stacked structure in which a molybdenum film, an aluminum film, and a molybdenum film are sequentially formed, in which a titanium film, an aluminum film, and a titanium film are sequentially formed, in which a titanium film, a titanium nitride film, an aluminum film, and a titanium film are sequentially formed, or the like (FIG. 2D).

Subsequently, a second interlayer insulating layer 63 is formed to cover the connection portion 61a, the first wire 61b, and the first interlayer insulating layer 60. As a material for the second interlayer insulating layer 63, a self-planarizing material such as acrylic, polyimide, or siloxane is preferably used. In this Embodiment, siloxane is used for the second interlayer insulating layer 63 (FIG. 2E).

Next, an insulating layer may be formed of silicon nitride or the like over the second interlayer insulating layer 63. The formation of the insulating layer can prevent the second interlayer insulating layer 63 from being etched more than necessary in etching a pixel electrode to be formed later. Note that the insulating layer is not necessarily formed when a selection ratio of the pixel electrode to the second interlayer insulating layer 63 in etching the pixel electrode is high. Subsequently, a contact hole which penetrates the second interlayer insulating layer 63 and reaches the connection portion 61a is formed.

Then, a light-transmitting conductive layer is formed to cover the contact hole and the second interlayer insulating layer 63 (or the insulating layer). Subsequently, the light-transmitting conductive layer is processed to form a lower electrode 64 of a thin-film light emitting element. Here, the lower electrode 64 is electrically in contact with the connection portion 61a.

The lower electrode 64 can be formed using conductive metal such as aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), lithium (Li), cesium (Cs), magnesium (Mg), calcium (Ca), strontium (Sr), or titanium (Ti); an alloy thereof such as an alloy of aluminum and silicon (Al—Si), an alloy of aluminum and titanium (Al—Ti), or an alloy of aluminum, silicon, and copper (Al—Si—Cu); nitride of a metal material such as titanium nitride (TiN); a metal compound such as indium tin oxide (ITO), ITO containing silicon, or indium zinc oxide (IZO) in which indium oxide is mixed with zinc oxide (ZnO) of 2 wt % to 20 wt %; or the like.

In addition, an electrode through which light is extracted is formed using a transparent conductive film. As a material for the transparent conductive film, an extremely thin film of metal such as Al or Ag as well as a metal compound such as indium tin oxide (ITO), ITO containing silicon (hereinafter referred to as ITSO), or indium zinc oxide (IZO) in which indium oxide is mixed with zinc oxide (ZnO) of 2 wt % to 20 wt %, is used. When light is extracted through an upper electrode 67, the lower electrode 64 can be formed of a highly reflective material (such as Al or Ag). In this Embodiment, ITSO is used for the lower electrode 64 (FIG. 3A).

Next, an insulating layer made of an organic material or an inorganic material is formed to cover the second interlayer insulating layer 63 (or the insulating layer) and the lower electrode 64. Subsequently, the insulating layer is processed so as to partially expose the lower electrode 64, thereby forming a partition wall 65. The partition wall 65 is preferably formed of a photosensitive organic material (such as acrylic or polyimide). Note that it may be formed of a non-photosensitive organic material or inorganic material. The partition wall 65 may be blacked by dispersing black colorant or dye such as titanium black or carbon nitride into the material of the partition wall 65 with the use of a dispersant or the like. Then, the black partition wall 65 may be used as a black matrix. An end face of the partition wall 65, facing an opening, preferably has curvature and a tapered shape in which the curvature changes continuously (FIG. 3B).

Next, a layer 66 containing a light emitting substance is formed. Then, the upper electrode 67 is formed to cover the layer 66 containing a light emitting substance. Accordingly, a light emitting element portion 93 where the layer 66 containing a light emitting substance is interposed between the lower electrode 64 and the upper electrode 67, can be manufactured. Then, light emission can be obtained by applying higher voltage to the lower electrode 64 than to the upper electrode 67. The upper electrode 67 can be formed using an electrode material similar to that of the lower electrode 64. In this Embodiment, aluminum is used for the upper electrode 67.

The layer 66 containing a light emitting substance is formed by an evaporation method, an ink-jet method, a spin coating method, a dip coating method, or the like. The layer 66 containing a light emitting substance contains the carbazole derivative described in Embodiment 1. The layer 66 containing a light emitting substance may be stacked layers of layers having respective functions or a single layer of a light emitting layer as described in Embodiment 2. In addition, the layer 66 containing a light emitting substance contains the carbazole derivative described in Embodiment 1 as a light emitting layer. The carbazole derivative described in Embodiment 1 may be included as one or both of a host and dopant of the light emitting layer. In addition, the carbazole derivative described in Embodiment 1 may be included as a layer other than the light emitting layer in the layer containing a light emitting substance or as a part thereof. In particular, the carbazole derivative of the present invention including a diarylamino group is superior also in a hole transporting property; thus, it can be used also as a hole transport layer. In addition, a material used in combination with the carbazole derivative described in Embodiment 1 may be a low molecular material, an intermediate molecular material (including an oligomer and a dendrimer), or a high molecular material. As a material used for the layer 66 containing a light emitting substance, a single layer or stacked layers of an organic compound is generally used, but the present invention includes a structure in which an inorganic compound is used for a part of a film formed of an organic compound.

Subsequently, a silicon oxide film containing nitrogen is formed as a passivation film by a plasma CVD method. In the case of using the silicon oxide film containing nitrogen, a silicon oxynitride film may be formed by a plasma CVD method using SiH₄, N₂O, and NH₃; SiH₄ and N₂O; or a gas in which SiH₄ and N₂O are diluted with Ar.

A silicon oxynitride hydride film formed from SiH₄, N₂O, and H₂ may be used as the passivation film. Naturally, the structure of the passivation film is not limited to a single-layer structure. The passivation film may have a single-layer structure or a stacked structure of another insulating layer containing silicon. In addition, a multilayer film of a carbon nitride film and a silicon nitride film, a multilayer film of styrene polymer, a silicon nitride film, or a diamond-like carbon film may be substituted for the silicon oxide film containing nitrogen.

Then, a display portion is sealed to protect the light emitting element from a substance which promotes deterioration (for example, moisture or the like). In the case of using a second substrate 94 for sealing, the second substrate 94 is attached using an insulating sealant so that an external connection portion is exposed. A space between the second substrate 94 and an element substrate may be filled with a dry inert gas such as nitrogen, or the second substrate 94 may be attached using a sealant formed entirely over the pixel portion. It is preferable to use an ultraviolet curing resin or the like as the sealant. The sealant may be mixed with a drying agent or particles for keeping a gap between the substrates constant. Then, a light emitting device is completed by attaching a flexible wiring board to the external connection portion.

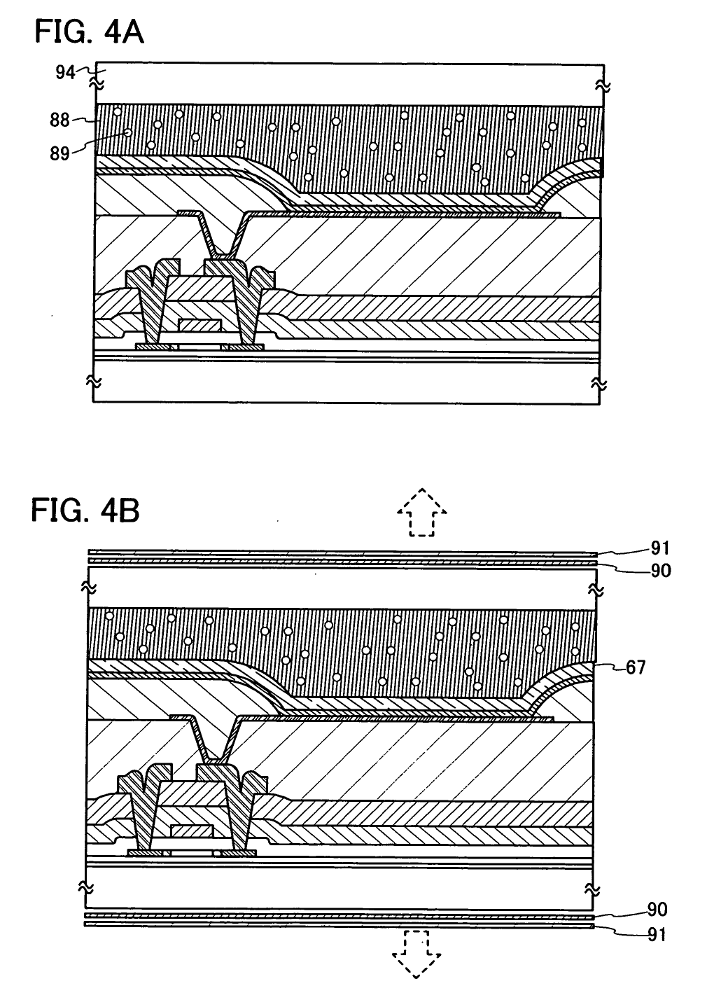

An example of a structure of the light emitting device manufactured as described above is explained with reference to FIGS. 4A and 4B. Note that portions having similar functions are denoted by the same reference numeral even if they have different shapes, and explanation thereof may be omitted. In this Embodiment, the thin film transistor 70 having an LDD structure is connected to the light emitting element portion 93 through the connection portion 61a.

FIG. 4A shows a structure in which the lower electrode 64 is formed of a light-transmitting conductive film and light emitted from the layer 66 containing a light emitting substance is extracted to the first substrate 50 side. Note that the second substrate 94 is fixed to the first substrate 50 with the use of a sealant or the like after the light emitting element portion 93 is formed. A space between the second substrate 94 and the element is filled with a light transmitting resin 88 or the like, and sealing is performed. Accordingly, the deterioration of the light emitting element portion 93 due to moisture can be prevented. The light transmitting resin 88 is preferably hygroscopic. When a highly light transmitting drying agent 89 is dispersed in the light transmitting resin 88, an influence of the moisture can be further reduced, which is more preferable.

FIG. 4B shows a structure in which both the lower electrode 64 and the upper electrode 67 are formed of a light transmitting conductive film and light can be extracted to both the first substrate 50 side and the second substrate 94 side. In this structure, a screen can be prevented from being transparent by providing each of the first substrate 50 and the second substrate 94 with an external polarizing plate 90; thus, visibility is increased. A protective film 91 is preferably provided outside the external polarizing plate 90.

Note that either an analog video signal or a digital video signal may be used for a light emitting device of the present invention having a display function. In the case of using a digital video signal, there are cases where the video signal uses voltage and the video signal uses current. As a video signal which is inputted to a pixel when a light emitting element emits light, there are a constant voltage video signal and a constant current video signal. As the constant voltage video signal, there are a signal in which voltage applied to a light emitting element is constant and a signal in which current applied to a light emitting element is constant. As the constant current video signal, there is a signal in which voltage applied to a light emitting element is constant and a signal in which current applied to a light emitting element is constant. Drive with the signal in which voltage applied to a light emitting element is constant is constant voltage drive, and that with the signal in which current applied to a light emitting element is constant is constant current drive. By constant current drive, constant current flows regardless of a change in resistance of the light emitting element. For a light emitting device of the present invention and a driving method thereof, any of the above-described driving methods may be employed.

Thus, the light emitting device of the present invention is a light emitting device with high reliability, in which a compound, into which the carbazole derivative described in Embodiment 1 is introduced as a substituent, is used for the layer 66 containing a light emitting substance. In addition, the light emitting device of the present invention is a light emitting device with high light emission efficiency, in which a compound, into which the carbazole derivative described in Embodiment 1 is introduced as a substituent, is used as a light emitting material.

This Embodiment can be appropriately combined with Embodiment 1 or 2.

### Embodiment 5

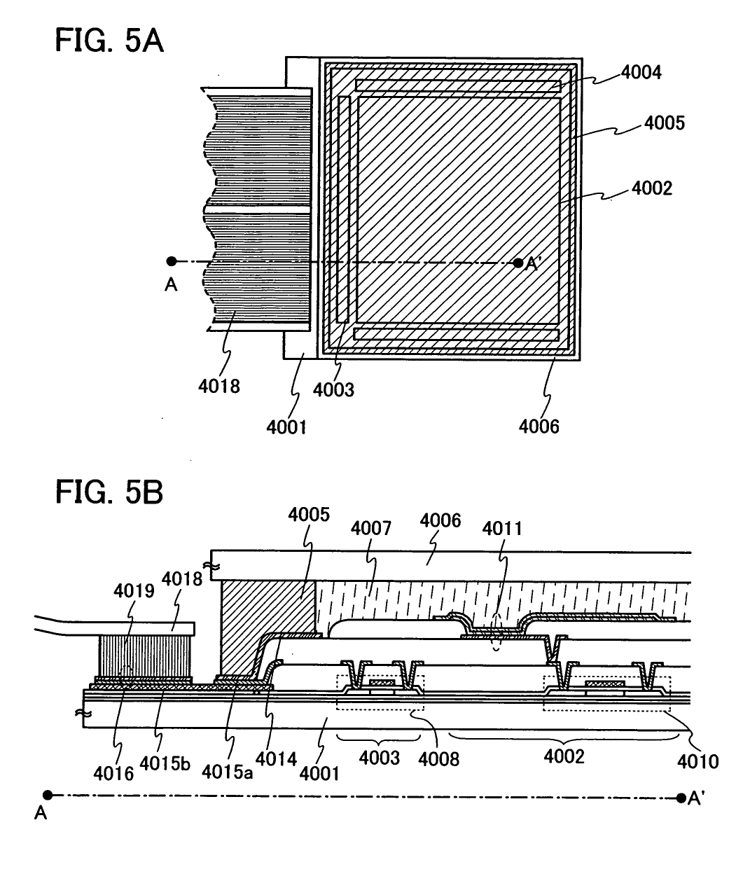

This Embodiment explains the appearance of a panel that is the light emitting device of the present invention with reference to FIGS. 5A and 5B. FIG. 5A is a top view of a panel in which a transistor and a light emitting element formed over a substrate are sealed with a sealant formed between the substrate and an opposing substrate 4006. FIG. 5B corresponds to a cross-sectional view of FIG. 5A. The light emitting element mounted on this panel has such a structure as described in Example 3.

A sealant 4005 is provided to surround a pixel portion 4002, a signal line driver circuit 4003, and a scan line driver circuit 4004 which are provided over a TFT substrate 4001. The opposing substrate 4006 is provided over the pixel portion 4002, the signal line driver circuit 4003, and the scan line driver circuit 4004. Thus, the pixel portion 4002, the signal line driver circuit 4003, and the scan line driver circuit 4004 are sealed with the TFT substrate 4001, the sealant 4005, and the opposing substrate 4006 as well as a filler 4007.

The pixel portion 4002, the signal line driver circuit 4003, and the scan line driver circuit 4004 which are provided over the TFT substrate 4001 include a plurality of thin film transistors. FIG. 5B shows a driver-circuit-portion thin film transistor 4008 included in the signal line driver circuit 4003 and a pixel-portion thin film transistor 4010 included in the pixel portion 4002.

A light emitting element portion 4011 is electrically connected to the pixel-portion thin film transistor 4010.

A first lead wire 4014 corresponds to a wire for supplying signals or power voltage to the pixel portion 4002, the signal line driver circuit 4003, and the scan line driver circuit 4004. The first lead wire 4014 is connected to a connection terminal 4016 through a second lead wire 4015a and a third lead wire 4015b. The connection terminal 4016 is electrically connected to a terminal included in a flexible printed circuit (FPC) 4018 through an anisotropic conductive film 4019.

Note that an ultraviolet curing resin or a thermosetting resin as well as an inert gas such as nitrogen or argon can be used as the filler 4007. Polyvinyl chloride, acrylic, polyimide, an epoxy resin, a silicon resin, polyvinyl butyral, or ethylene vinylene acetate can be used.

Note that the light emitting device of the present invention includes, in its category, a panel provided with a pixel portion including a light emitting element and a module in which an IC is mounted on the panel.

The signal line driver circuit 4003, the scan line driver circuit 4004, and the IC which are signal processing circuits as described above are control circuits of light emitting elements, and a light emitting device and an electronic device mounted with these control circuits can display various images on the panel by the control circuits controlling lighting and non-lighting or luminance of the light emitting elements. Note that a signal processing circuit which is formed over an external circuit board connected through the FPC 4018 is also a control circuit.

The light emitting device of the present invention as described above is a light emitting device with a highly reliable pixel portion because it includes the light emitting element described in Embodiment 2 as a light emitting element included in the pixel portion. In addition, the light emitting device of the present invention is a light emitting device with high light emission efficiency because it includes the light emitting element described in Embodiment 2 as a light emitting element included in the pixel portion.

This Embodiment can be appropriately combined with any of Embodiments 1 to 4.

### Embodiment 6

This Embodiment explains a pixel circuit and a protective circuit which are included in the panel or module described in Embodiment 5, and operation thereof. Note that the cross-sectional views shown in FIGS. 2A to 3C correspond to cross-sectional views of a driver TFT 1403 and a light emitting element portion 1405.

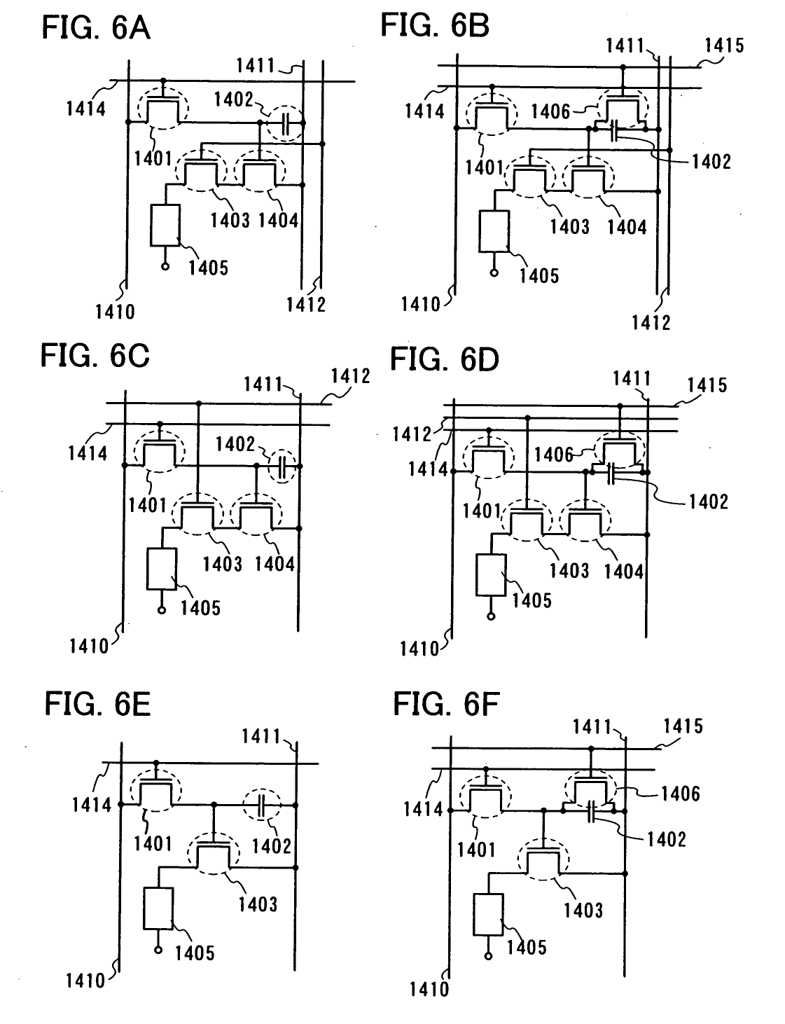

A pixel shown in FIG. 6A has a structure in which a signal line 1410 and power supply lines 1411 and 1412 are arranged in a column direction and a scan line 1414 is arranged in a row direction. In addition, the pixel includes a switching TFT 1401, the driver TFT 1403, a current control TFT 1404, a capacitor element 1402, and the light emitting element portion 1405.

A pixel shown in FIG. 6C has the same structure as that of the pixel shown in FIG. 6A, except that a gate of the driver TFT 1403 is connected to the power supply line 1412 arranged in a row direction. In other words, equivalent circuit diagrams of both pixels shown in FIGS. 6A and 6C are the same. Note that the power supply line 1412 arranged in a column direction (FIG. 6A) and the power supply line 1412 arranged in a row direction (FIG. 6C) are formed using conductive layers in different layers. Here, the pixels are separately shown in FIGS. 6A and 6C to show that wires each connected to the gate of the driver TFT 1403 are formed in different layers.

In each of the pixels shown in FIGS. 6A and 6C, the driver TFT 1403 is connected in series to the current control TFT 1404. A channel length L (the driver TFT 1403) and a channel width W (the driver TFT 1403) of the driver TFT 1403 and a channel length L (the current control TFT 1404) and a channel width W (the current control TFT 1404) of the current control TFT 1404 are preferably set so as to satisfy L (the driver TFT 1403)/W (the driver TFT 1403): L (the current control TFT 1404)/W (the current control TFT 1404)=5 to 6000:1.

Note that the driver TFT 1403 operates in a saturation region and has a role of controlling the amount of current flowing to the light emitting element portion 1405. The current control TFT 1404 operates in a linear region and has a role of controlling the supply of current to the light emitting element portion 1405. It is preferable from the viewpoint of the manufacturing process that both TFTs have the same conductivity type. In this Embodiment, both TFTs are formed as n-channel TFTs. Further, the driver TFT 1403 may be a depletion mode TFT as well as an enhancement mode TFT. In the light emitting device of the present invention having the above structure, the current control TFT 1404 operates in a linear region, so that slight variation in Vgs (gate-source voltage) of the current control TFT 1404 does not affect the amount of current of the light emitting element portion 1405. In other words, the amount of current of the light emitting element portion 1405 can be determined depending on the driver TFT 1403 which operates in a saturation region. According to the above-described structure, luminance variation of the light emitting element, which is caused by characteristics variation of the TFT, can be suppressed, and a light emitting device with high image quality can be provided.

In each of pixels shown in FIGS. 6A to 6D, the switching TFT 1401 controls the input of a video signal to the pixel. When the switching TFT 1401 is turned on, the video signal is inputted to the pixel. Then, voltage of that video signal is held at the capacitor element 1402. Note that, although each of FIGS. 6A and 6C shows a structure provided with the capacitor element 1402, the present invention is not limited thereto. When a capacitance value of a gate capacitor or the like is sufficient for holding a video signal, the capacitor element 1402 is not necessarily provided.

The pixel shown in FIG. 6B has the same structure as that of the pixel shown in FIG. 6A, except that an erase TFT 1406 and a scan line 1415 are added. In the same manner, the pixel shown in FIG. 6D has the same structure as that of the pixel shown in FIG. 6C, except that an erase TFT 1406 and a scan line 1415 are added.

The erase TFT 1406 is controlled to be turned on or off by the scan line 1415 that is newly provided. When the erase TFT 1406 is turned on, an electric charge held at the capacitor element 1402 is discharged, and the current control TFT 1404 is turned off. In other words, it is possible to make a state in which current is forced not to flow through the light emitting element portion 1405 by providing the erase TFT 1406. Accordingly, in the structures of FIGS. 6B and 6D, a lighting period can be started simultaneously with or immediately after a start of a write period without waiting for writing of signals in all pixels. Therefore, a duty ratio can be increased.

A pixel shown in FIG. 6E has a structure in which a signal line 1410 and a power supply line 1411 are arranged in a column direction, and a scan line 1414 is arranged in a row direction. In addition, the pixel includes a switching TFT 1401, a driver TFT 1403, a capacitor element 1402, and a light emitting element portion 1405. A pixel shown in FIG. 6F has the same structure as that of the pixel shown in FIG. 6E, except that an erase TFT 1406 and a scan line 1415 are added. Note that a duty ratio can be increased also in the structure of FIG. 6F by providing the erase TFT 1406.

As described above, various pixel circuits can be employed in the present invention. In particular, in the case of forming a thin film transistor with an amorphous semiconductor film, the size of a semiconductor layer of the driver TFT 1403 is preferably large. Therefore, the above-described pixel circuit is preferably a top emission type which emits light from a light emitting stacked body through a sealing substrate.

Such an active matrix light emitting device is considered to be advantageous in that it can be driven at low voltage when a pixel density is increased, because each pixel is provided with a TFT.

Although this Embodiment explains an active matrix light emitting device in which each pixel is provided with a TFT, the present invention can be applied also to a passive matrix light emitting device. A passive matrix light emitting device is advantageous because it can be manufactured by an easy method. In addition, since a TFT is not provided for every pixel, a high aperture ratio can be obtained. In the case of a light emitting device which emits light to both sides of a light emitting stacked body, an aperture ratio can be increased by using the passive matrix light emitting device.

Subsequently, the case of connecting a diode as a protective circuit to the scan line 1414 and the signal line 1410 is explained using an equivalent circuit shown in FIG. 6E.

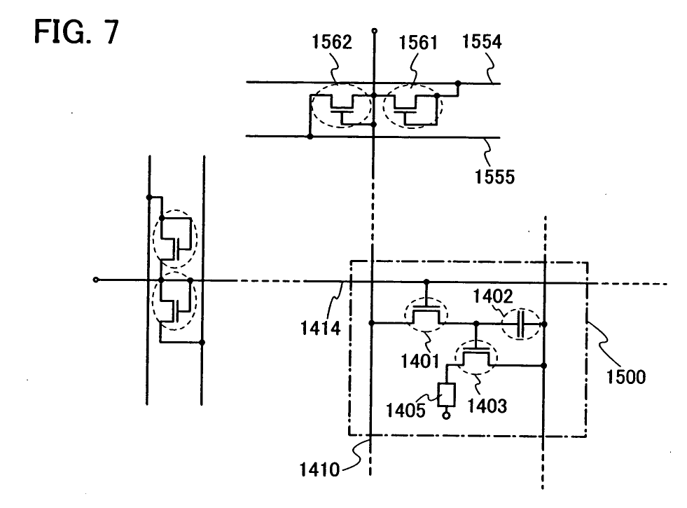

In FIG. 7, a pixel portion 1500 is provided with a switching TFT 1401, a driver TFT 1403, a capacitor element 1402, and a light emitting element portion 1405. A signal line 1410 is provided with protective-circuit diodes 1561 and 1562. Each of the protective-circuit diodes 1561 and 1562 can be manufactured by the method in the above Embodiment as is the case with the switching TFT 1401 or the driver TFT 1403. Therefore, each diode includes a gate electrode, a semiconductor layer, a source electrode, a drain electrode, and the like. Each of the protective-circuit diodes 1561 and 1562 is operated as a diode by connecting the gate electrode to the source or drain electrode.

Common potential lines 1554 and 1555 connected to the diodes are formed in the same layer as the gate electrode. Therefore, a contact hole needs to be formed in a gate insulating layer to connect each of the common potential lines to the source or drain electrode of the diode.

A diode provided for the scan line 1414 also has a similar structure.

According to the invention as described above, a protective diode to be provided at an input stage can be formed at the same time as the TFT. Note that the position where the protective diode is formed is not limited thereto. The protective diode can be provided between a driver circuit and a pixel.

This Embodiment can be appropriately combined with any of Embodiments 1 to 5.

The light emitting device of the present invention having such a protective circuit can be a light emitting device with high reliability. By combining the above protective circuit, reliability as a light emitting device can further be increased.

### Embodiment 7

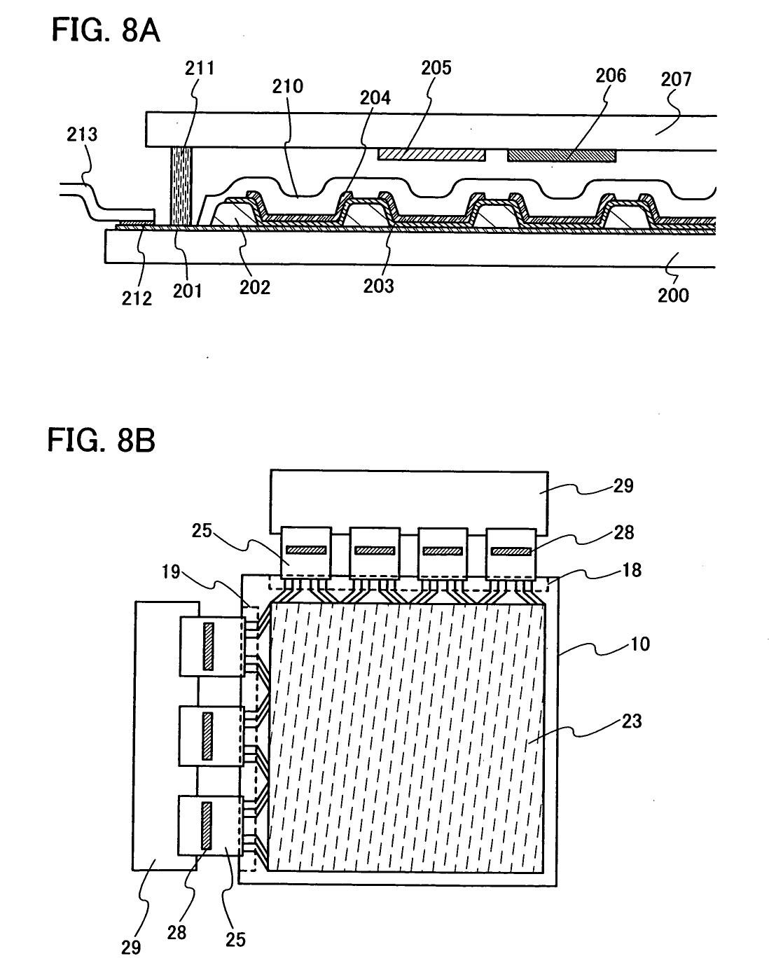

FIG. 8A shows an example of a structure of the light emitting device of the present invention. FIG. 8A shows a partial cross-sectional view of a pixel portion in a passive matrix light emitting device having a forward tapered structure. The light emitting device of the present invention shown in FIG. 8A includes a first substrate 200, a first electrode 201 of a light emitting element, a partition wall 202, a light emitting stacked body 203, a second electrode 204 of the light emitting element, and a second substrate 207.

A portion serving as a pixel corresponds to a portion where the light emitting stacked body 203 is interposed between the first electrode 201 and the second electrode 204. The first electrodes 201 and the second electrodes 204 are formed in stripes to be perpendicular to each other, and the portion serving as a pixel is formed at the intersection. The partition wall 202 is formed parallel to the second electrode 204, and the portion serving as a pixel is insulated by the partition wall 202 from another portion serving as a pixel using the same first electrode 201.

In this Embodiment, Embodiment 4 may be referred to for specific materials and structures of the first electrode 201, the second electrode 204, and the light emitting stacked body 203.

In addition, the first substrate 200, the partition wall 202, and the second substrate 207 in FIG. 8A correspond to the first substrate 50, the partition wall 65, and the second substrate 94 in Embodiment 4, respectively. Since structures, materials, and effects thereof are similar to those in Embodiment 4, repetitive explanation is omitted. Refer to the description in Embodiment 4.

In the light emitting device, a protective film 210 is formed to prevent the entry of moisture or the like, and the second substrate 207 of glass, stone, a ceramic material such as alumina, a synthetic material, or the like is firmly attached with a sealing adhesive 211. An external input terminal is connected to an external circuit using a flexible printed wiring board 213 through an anisotropic conductive film 212. The protective film 210 may be formed using a stacked body of carbon nitride and silicon nitride for reducing stress and improving a gas barrier property, as well as silicon nitride.

FIG. 8B shows a state of a module which is formed by connecting an external circuit to the panel shown in FIG. 8A. In the module, flexible printed wiring boards 25 are firmly attached to external input terminal portions 18 and 19, and are electrically connected to external circuit boards provided with power supply circuits and signal processing circuits. A driver IC 28 which is one of external circuits may be mounted by either a COG method or a TAB method. FIG. 8B shows a state in which the driver IC 28 which is one of external circuits is mounted by a COG method. The signal processing circuits formed over the external circuit boards and the driver ICs 28 are control circuits of light emitting elements, and a light emitting device and an electronic device mounted with the control circuits can display various images on the panel by the control circuits controlling lighting and non-lighting or luminance of the light emitting elements.

Note that the panel and the module correspond to one mode of the light emitting device of the present invention, and both are included in the scope of the present invention.

### Embodiment 8

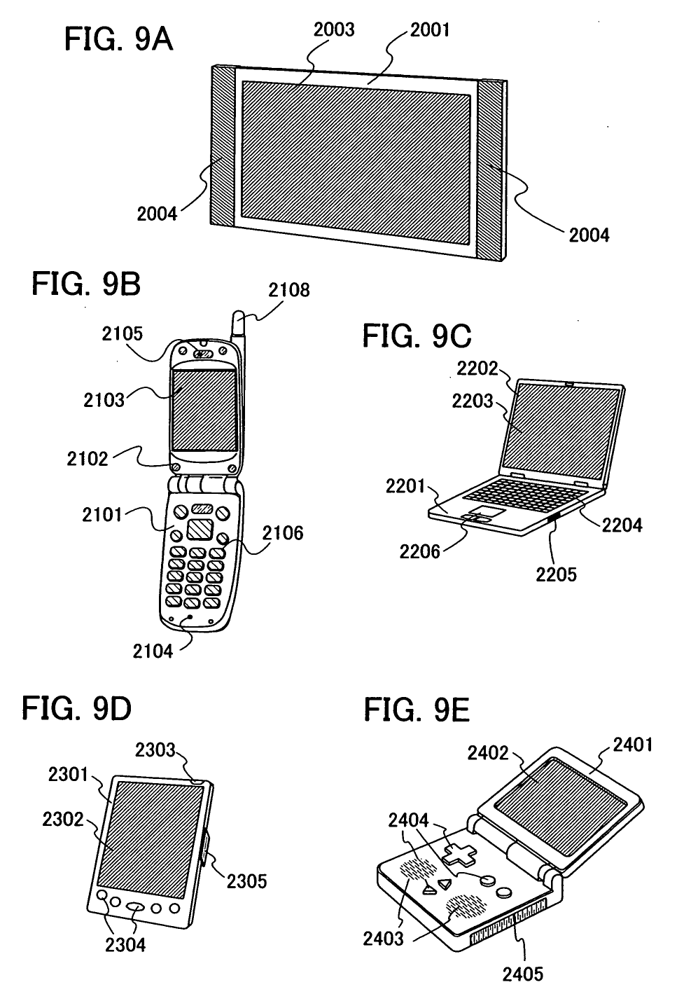

Examples of the electronic device of the present invention mounted with the light emitting device (module) of the present invention are as follows: a camera such as a video camera or a digital camera, a goggle type display (head-mounted display), a navigation system, a sound reproduction device (such as a car audio component), a computer, a game machine, a portable information terminal (such as a mobile computer, a mobile phone, a portable game machine, or an electronic book), an image reproduction device equipped with a recording medium (specifically, a device which reproduces a recording medium such as a digital versatile disc (DVD) and which is equipped with a display for displaying an image), and the like. Specific examples of the electronic devices are shown in FIGS. 9A to 9E.

FIG. 9A shows a light emitting device, which corresponds to a TV set, a monitor of a personal computer, or the like. The light emitting device includes a chassis 2001, a display portion 2003, a speaker portion 2004, and the like. The light emitting device of the present invention is a light emitting device with high reliability, of which display portion 2003 has high display quality. A pixel portion is preferably provided with a polarizing plate or a circularly polarizing plate to enhance contrast. For example, a quarter-wave plate, a half-wave plate, and a polarizing plate are preferably formed sequentially over a sealing substrate. Further, an anti-reflective film may be provided over the polarizing plate.

FIG. 9B shows a mobile phone, which includes a main body 2101, a chassis 2102, a display portion 2103, an audio input portion 2104, an audio output portion 2105, an operation key 2106, an antenna 2108, and the like. The mobile phone of the present invention is a mobile phone with high reliability, of which display portion 2103 has high display quality.

FIG. 9C shows a computer, which includes a main body 2201, a chassis 2202, a display portion 2203, a keyboard 2204, an external connection port 2205, a pointing mouse 2206, and the like. The computer of the present invention is a computer with high reliability, of which display portion 2203 has high display quality. Although the notebook computer is shown in FIG. 9C as an example, the present invention can also be applied to a desktop computer in which a hard disk and a display portion are combined with each other, and the like.

FIG. 9D shows a mobile computer, which includes a main body 2301, a display portion 2302, a switch 2303, an operation key 2304, an infrared port 2305, and the like. The mobile computer of the invention is a mobile computer with high reliability, of which display portion 2302 has high display quality.

FIG. 9E shows a portable game machine, which includes a chassis 2401, a display portion 2402, a speaker portion 2403, an operation key 2404, a recording medium insertion portion 2405, and the like. The portable game machine of the present invention is a portable game machine with high reliability, of which display portion 2402 has high display quality.

As described above, the applicable range of the present invention is so wide that the present invention can be applied to electronic devices of various fields.

This Embodiment can be appropriately combined with any of Embodiments 1 to 5.

### EXAMPLE 1

A synthesis method of a compound represented by the following structural formula (1), 3-(N,N-diphenyl)aminocarbazole as one example of a material of the present invention is hereinafter described.

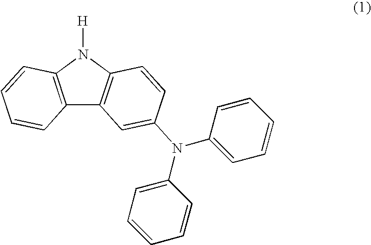

### (1) Synthesis of 3-iodocarbazole

After gradually adding 4.5 g (20 mmol) of N-iodosuccinimide (NIS) to a solution of 3.5 g (21 mmol) of carbazole in 450 mL of a glacial acetic acid, the mixture was stirred at a room temperature for 12 hours. Subsequently, the reaction mixture was dripped into about 750 mL of water. After dripping, a precipitate was filtered. Then, the filtered precipitate was washed with water. After washing, the precipitate was dissolved in about 150 mL of ethyl acetate. This solution was washed with an aqueous sodium hydrogen carbonate solution, water, and a saturated aqueous sodium chloride solution in this order. After washing, magnesium sulfate was added, and the solution was dried. After drying, the solution was filtered. Subsequently, the filtered solution was concentrated, thereby obtaining 6.0 g of 3-iodocarbazole as a white powder (yield: 97%). A synthesis scheme of 3-iodocarbazole is shown below.

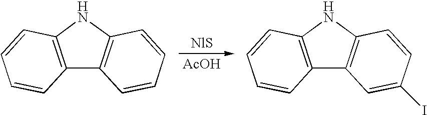

### (2) Synthesis of 9-acetyl-3-iodocarbazole

In a nitrogen atmosphere, 1.0 g (oiliness: 60%, 25 mmol) of ice-cold sodium hydride was suspended in 35 mL of dry tetrahydrofuran (THF). Into that suspension, a solution of 4.7 g (16 mmol) of 3-iodocarbazole synthesized by the above method in 50 mL of THF was gradually dripped. Subsequently, the mixture was stirred for 30 minutes. After dripping 2.0 g (25 mmol) of acetyl chloride into the mixture, the mixture was stirred for one hour. Subsequently, the mixture was further stirred for 12 hours at a room temperature. About 30 mL of water was added to the mixture. An organic layer was washed with water and a saturated aqueous sodium chloride solution. Then, a water layer was extracted with about 50 mL of ethyl acetate and mixed with the organic layer. Magnesium sulfate was added to the organic layer and then dried. After filtering the dried organic layer, the filtered solution was concentrated. The obtained solid was washed with about 20 mL of hexane, thereby obtaining 5.1 g of 9-acetyl-3-iodocarbazole as a milk-white powder (yield: 94%). A synthesis scheme of 9-acetyl-3-iodocarbazole is shown below.

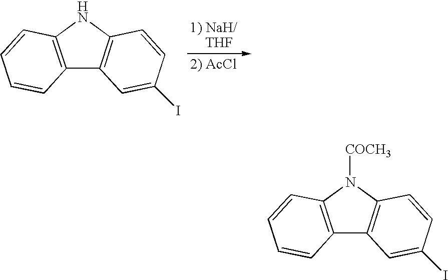

### (3) Synthesis of 9-acetyl-3-(N,N-diphenyl)aminocarbazole

In a nitrogen atmosphere, a suspension of 3.4 g (10 mmol) of 9-acetyl-3-iodocarbazole, 2.0 g (12 mmol) of diphenylamine, and 2.1 g (15 mmol) of copper(I) oxide in 70 mL of N,N-dimethylacetoamide was stirred for 20 hours while heating at 160° C. After cooling the suspension stirred while heating to a room temperature, about 50 mL of methanol was added. Then, the mixture was filtered through Celite®. After concentrating the obtained filtrate, the residue was purified by silica gel column chromatography (a developing solution of toluene:hexane=1:1), thereby obtaining 1.8 g of 9-acetyl-3-(N,N-diphenyl)aminocarbazole as a cream-colored powder (yield: 48%). A synthesis scheme of 9-acetyl-3-(N,N-diphenyl)aminocarbazole is shown below.

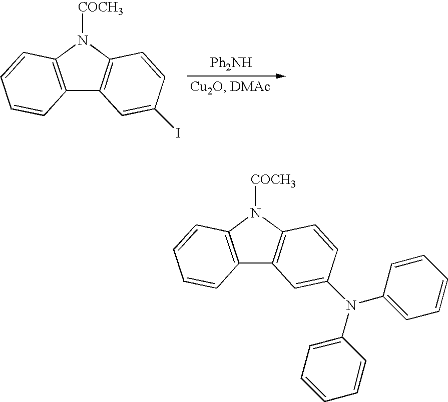

### (4) Synthesis of 3-(N,N-diphenyl)aminocarbazole

After adding 3 mL of an aqueous solution of 2.8 g of potassium hydroxide and 50 mL of dimethylsulfide to a solution of 1.8 g (5 mmol) of 9-acetyl-3-(N,N-diphenyl)aminocarbazole in 50 mL of THF, the mixture was stirred for 5 hours while heating at 100° C. Subsequently, about 100 mL of water was added. Then, an organic layer was extracted with about 150 mL of ethyl acetate. The organic layer was dried with magnesium sulfate, filtered, and then concentrated. Then, the residue was purified by silica gel column chromatography (a developing solution of toluene:hexane=1:1), thereby obtaining 400 mg of 3-(N,N-diphenyl)aminocarbazole that is one kind of the carbazole derivative of the present invention as a beige powder (yield: 27%). A synthesis scheme of 3-(N,N-diphenyl)aminocarbazole is shown below.

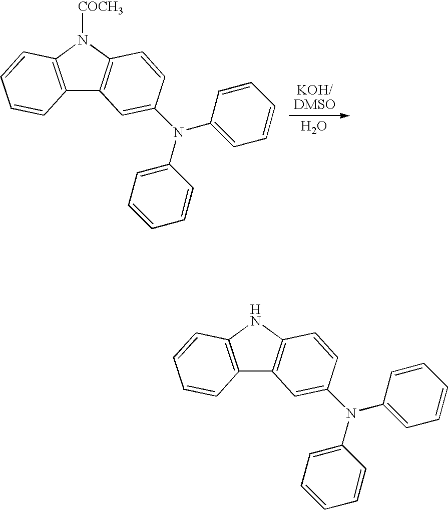

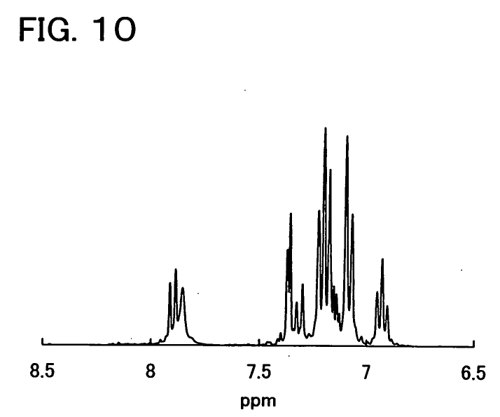

NMR data of the obtained 3-(N,N-diphenyl)aminocarbazole are shown below. ¹H NMR (300 MHz, CDCl₃) δ=6.93 (d,J=7.5 Hz, 2H), 7.08 (d,J=7.8 Hz, 4H), 7.13-7.22 (m, 7H), 7.03-7.37 (m, 3H), 7.85 (s, 1H), 7.90 (d,J=7.8 Hz, 1H). An NMR chart of 3-(N,N-diphenyl)aminocarbazole is shown in FIG. 10.

### EXAMPLE 2

A synthesis method of 9-{4-[3-(N,N-diphenylamino)-N-carbazolyl]phenyl}-10-phenylanthracene (hereinafter referred to as CzA1PA) represented by the following formula (42) as an example of the compound into which the carbazole derivative of the present invention is introduced as a substituent is explained.

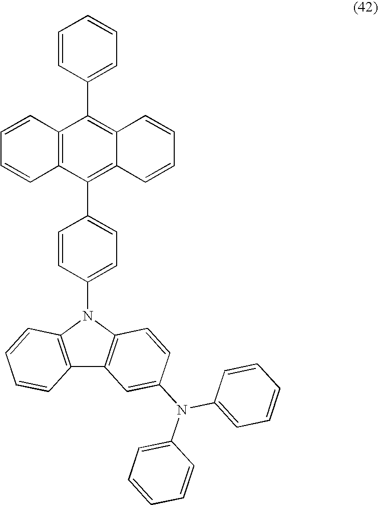

### Step 1: Synthesis of 9-phenyl-10-(4-bromophenyl)anthracene

### (1) Synthesis of 9-phenylanthracene

After mixing 5.4 g (21.1 mmol) of 9-bromoanthracene, 2.6 g (21.1 mmol) of phenylboronic acid, 60 mg (0.21 mmol) of palladium acetate, 10 mL of a 2 mol/L aqueous potassium carbonate solution, 263 mg (0.84 mmol) of tri(orthotolyl)phosphine, and 20 mL of dimethoxyethane, the mixture was stirred for 9 hours at 80° C. After the reaction, the precipitated solid was recovered by suction filtration. Then, the recovered solid was dissolved in toluene and filtered through florisil, Celite®, and alumina. The filtrate was washed with water and an aqueous sodium chloride solution. After washing, the filtrate was dried with magnesium sulfate and then filtered naturally. Subsequently, the filtrate was concentrated, thereby obtaining 4.0 g of 9-phenylanthracene as a light-brown solid (yield: 75%). A synthesis scheme of 9-phenylanthracene from 9-bromoanthracene is shown below.

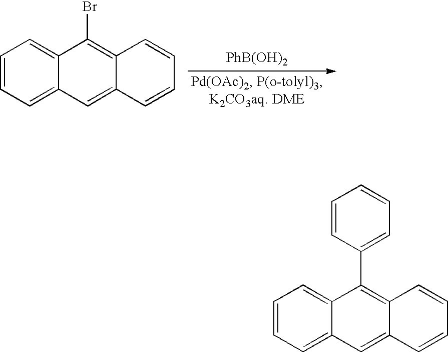

### (2) Synthesis of 9-bromo-10-phenylanthracene

6.0 g (23.7 mmol) of 9-phenylanthracene synthesized by the above method was dissolved in 80 mL of carbon tetrachloride. A solution of 3.80 g (21.1 mmol) of bromine in 10 mL of carbon tetrachloride was dripped into the reaction solution using a dropping funnel. After the completion of dripping, the mixture was stirred for one hour at a room temperature. An aqueous sodium thiosulfate solution was added to stop the reaction. An organic layer was washed with an aqueous sodium hydroxide solution and a saturated aqueous sodium chloride solution in this order. After washing, the organic layer was dried with magnesium sulfate and then filtered naturally. After concentrating, the organic layer was dissolved in toluene. Then, the solution was filtered through florisil, Celite®, and alumina. After concentrating the filtrate, the filtrate was recrystallized with dichloromethane and hexane, thereby obtaining 7.0 g of 9-bromo-10-phenylanthracene as a light yellow solid (yield: 89%). A synthesis scheme of 9-bromo-10-phenylanthracene from 9-phenylanthracene is shown below.

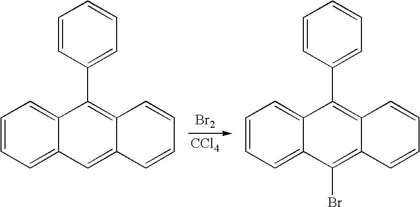

### (3) Synthesis of 9-iodo-10-phenylanthracene

After dissolving 3.33 g (10 mmol) of 9-bromo-10-phenylanthracene in 80 mL of THF, the solution was cooled to −78° C. Then, 7.5 mL (1.6 M, 12.0 mmol) of n-BuLi was dripped, and the mixture was stirred for one hour. Next, a solution of 5 g (20.0 mmol) of iodine in 20 mL of THF was dripped at −78° C., and then the mixture was further stirred for 2 hours. After the reaction, an aqueous sodium thiosulfate solution was added to stop reaction. An organic layer was washed with an aqueous sodium thiosulfate solution and a saturated aqueous sodium chloride solution in this order. After washing, the organic layer was dried with magnesium sulfate and then filtered naturally. After concentrating the filtrate, the filtrate was recrystallized with ethanol, thereby obtaining 3.1 g of 9-iodo-10-phenylanthracene as a light yellow solid (yield: 83%). A synthesis scheme of 9-iodo-10-phenylanthracene from 9-bromo-10-phenylanthracene is shown below.

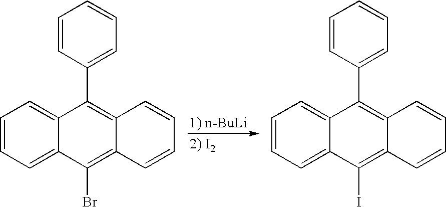

### (4) Synthesis of 9-phenyl-10-(4-bromophenyl)anthracene

A mixture of 1.0 g (2.63 mmol) of 9-iodo-10-phenylanthracene, 542 mg (2.70 mmol) of p-bromo phenylboronic acid, 46 mg (0.03 mmol) of tetrakis(triphenylphosphine)palladium, 3 mL of a 2 mol/L aqueous potassium carbonate solution, and 10 mL of toluene was stirred for 9 hours at 80° C. After the reaction, toluene was added, and the mixture was filtered through florisil, Celite®, and alumina. The filtrate was washed with water and a saturated aqueous sodium chloride solution in this order and then dried with magnesium sulfate. Subsequently, the filtrate was filtered naturally. After concentrating the filtrate, the filtrate was recrystallized with chloroform and hexane, thereby obtaining 562 mg of 9-phenyl-10-(4-bromophenyl)anthracene as a light-brown solid (yield: 45%). A synthesis scheme of 9-phenyl-10-(4-bromophenyl)anthracene from 9-iodo-10-phenylanthracene is shown below.

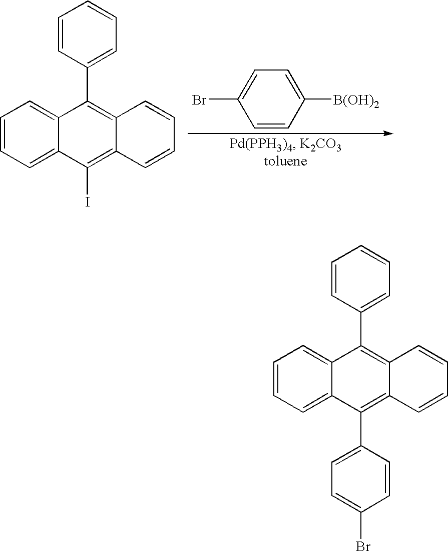

### Step 2: Synthesis of CzA1PA

A suspension, in 3.5 mL of xylene, of 340 mg (1.0 mmol) of 3-(N,N-diphenyl)aminocarbazole that is the carbazole derivative of the present invention, 490 mg (1.2 mmol) of 9-phenyl-10-(4-bromophenyl)anthracene, 58 mg (0.1 mmol) of bis(dibenzylideneacetone)palladium(O), and 300 mg (3.0 mmol) of t-butoxy sodium was deaerated for 3 minutes. After adding 0.5 mL of tri(t-butyl)phosphine (a 10 wt % hexane solution), the mixture was stirred for 4.5 hours while heating at 90° C. After adding about 300 mL of toluene, the mixture was filtered through florisil, alumina, and Celite®. The obtained filtrate was washed with water and a saturated aqueous sodium chloride solution in this order. After washing, magnesium sulfate was added and the mixture was dried. The mixture was filtered and then concentrated. The residue was purified by silica gel chromatography (a developing solution of toluene:hexane=3:7), thereby obtaining 300 mg of CzA1PA as a cream-colored powder (yield: 45%). A synthesis scheme of CzA1PA by coupling reaction of 3-(N,N-diphenyl)aminocarbazole and 9-phenyl-10-(4-bromophenyl)anthracene is shown below.

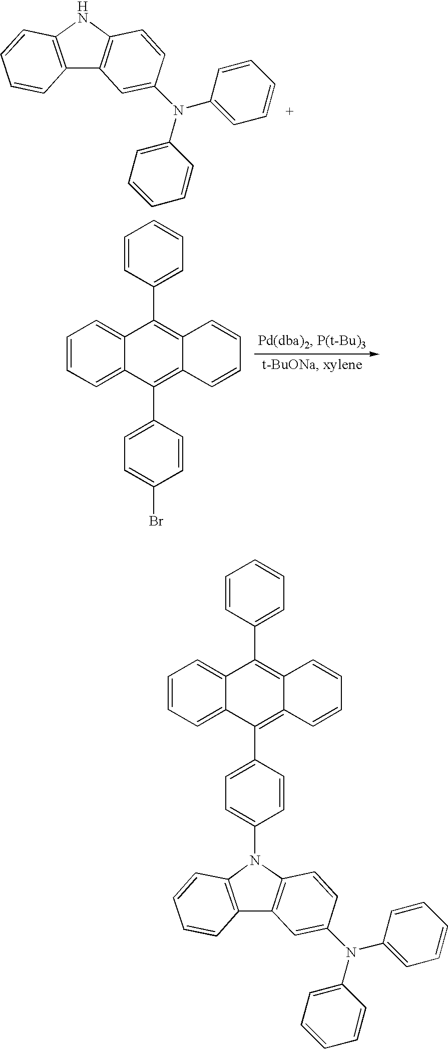

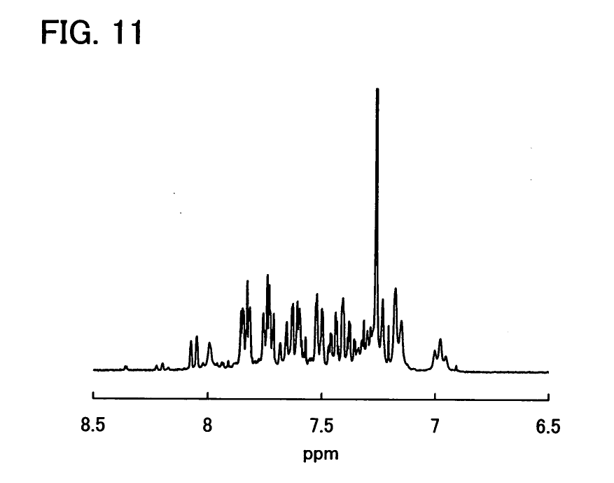

NMR data of the obtained CzA1PA are shown below. ¹H NMR (300 MHz, CDCl₃) δ=6.98 (d,J=7.2 Hz, 2H), 7.16 (d,J=7.8 Hz, 4H), 7.20-7.86 (m, 26H), 7.99 (s, 1H), 8.06 (d,J=7.8 Hz, 1H). An NMR chart of CzA1PA is shown in FIG. 11.

A thermogravimetry-differential thermal analysis (TG-DTA) of CzA1PA was performed. By using a thermo-gravimetric/differential thermal analyzer (TG/DTA SCC/5200, manufactured by Seiko Instruments Inc.), thermophysical properties were measured at a temperature rising rate of 10° C./min in a nitrogen atmosphere. As a result, from the relationship between gravity and temperature (thermogravimetry), a gravity reduction start temperature was 420° C. under normal pressure. As a result of measuring a glass transition temperature and a melting point of CzA1PA with a differential scanning calorimeter (Pyris 1 DSC, manufactured by Perkin Elmer Co., Ltd.), it was found that they were 153° C. and 313° C., respectively, and CzA1PA was thermally stable.

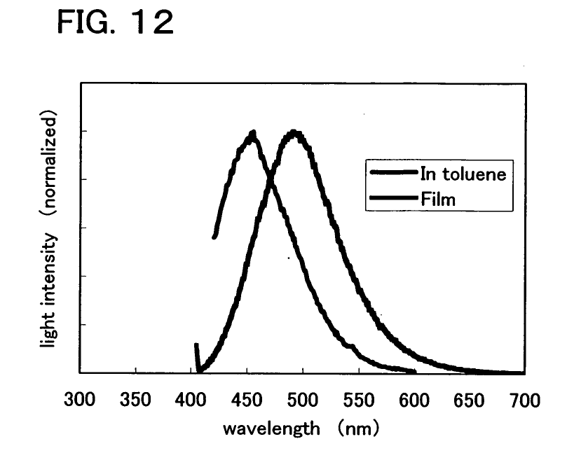

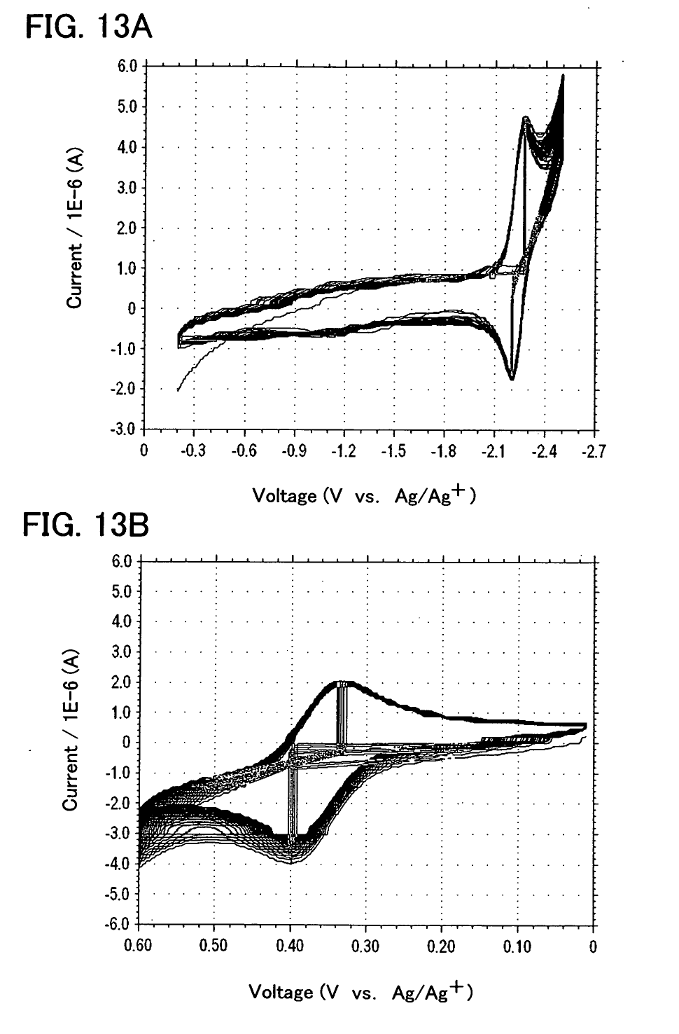

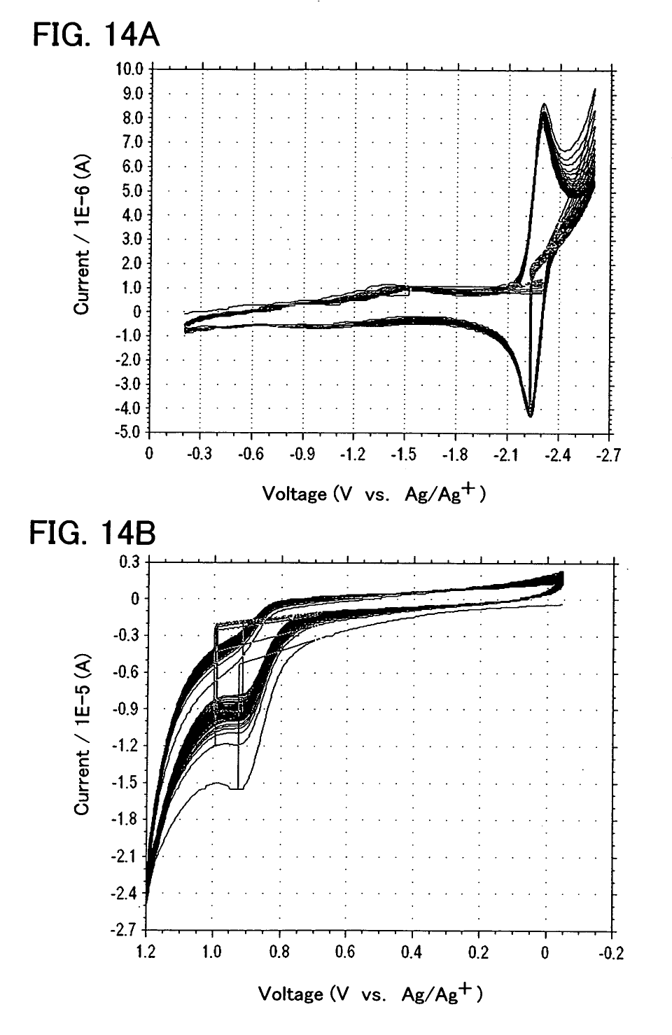

In addition, absorption spectra of a toluene solution of CzA1PA and a thin film of CzA1PA were measured. Absorption based on anthracene was observed at approximately 370 nm and 400 nm. Emission spectra of a toluene solution of CzA1PA and a thin film of CzA1PA are shown in FIG. 12. In FIG. 12, the horizontal axis indicates wavelength (nm) and the vertical axis indicates emission intensity (arbitrary unit). The maximum emission wavelength was 453 nm (excitation wavelength: 370 nm) in the case of the toluene solution and 491 nm (excitation wavelength: 380 nm) in the case of the thin film, and it was found that blue light emission was obtained.

Further, the HOMO level and LUMO level of the thin film of CzA1PA were measured. A value of the HOMO level was obtained by converting a value of ionization potential measured using a photoelectron spectrometer (AC-2, manufactured by Riken Keiki Co., Ltd.) into a negative value. A value of the LUMO level was obtained by using an absorption edge of the thin film as an energy gap and adding the value of the absorption edge to the value of the HOMO level. As a result, the HOMO level and the LUMO level were −5.30 eV and −2.38 eV, respectively, which showed a significantly large energy gap of 2.82 eV.

### EXAMPLE 3

This Example describes electrochemical stability of CzA1PA. CzA1PA can be synthesized by such a method as in Example 2 and is one kind of the compound into which the carbazole derivative of the present invention (3-(N,N-diphenyl)animocarbazole) is introduced as a substituent. For comparison, electrochemical stability of diphenylanthracene (abbr.: DPAnth) having a structure in which a 3-(N,N-diphenyl)aminocarbazole skeleton is removed from CzA1PA is also described.

Electrochemical stability was evaluated by a cyclic voltammetry (CV) measurement. An electrochemical analyzer (ALS model 600A, manufactured by BAS Inc.) was used for the CV measurement. As for a solution used in the CV measurement, dehydrated dimethylformamide (DMF) was used as a solvent. Tetra-n-butylammonium perchlorate (n-Bu₄NClO₄), which was a supporting electrolyte, was dissolved in the solvent so that a concentration of tetra-n-butylammonium perchlorate was 100 mM. Further, an object to be measured was dissolved therein and prepared so that a concentration thereof was 1 mmol/L. Further, a platinum electrode (PTE platinum electrode, manufactured by BAS Inc.) was used as a work electrode. A platinum electrode (VC-3 Pt counter electrode (5 cm), manufactured by BAS Inc.) was used as an auxiliary electrode. An Ag/Ag⁺ electrode (RE 5 nonaqueous reference electrode, manufactured by BAS Inc.) was used as a reference electrode. With a scan rate of 0.1 V/sec, scanning was performed 200 times each in the case of applying a negative potential (hereinafter referred to as an oxidation side) and in the case of applying a positive potential (hereinafter referred to as a reduction side).

FIGS. 13A and 13B show CV charts of CzA1PA, and FIGS. 14A and 14B show CV charts of DPAnth. Note that FIGS. 13A and 14A show measurement results on the oxidation side, and FIGS. 13B and 14B show measurement results on the reduction side.

CzA1PA that is the compound into which the carbazole derivative of the present invention is introduced as a substituent shows reversible peaks on both the oxidation side and the reduction side. Even when the oxidation-reduction or reduction-oxidation cycle is repeated 200 times, the peak intensity hardly changes. On the other hand, DPAnth behaves reversibly on the reduction side and has an almost similar peak even after 200 cycles. Meanwhile, oxidation peak intensity gradually decreases on the oxidation side. This shows that CzA1PA reversibly returns to an original neutral molecule in the oxidation-reduction cycle whereas DPAnth is accompanied by a side reaction of oxidation and does not return to an original neutral molecule in the following reduction. In other words, it shows that DPAnth exhibits low reversibility to oxidation-reduction.

This result shows that the introduction of 3-(N,N-diphenyl)aminocarbazole skeleton that is the carbazole derivative of the present invention into DPAnth can improve electrochemical stability of a compound into which the carbazole derivative is introduced.

Thus, the carbazole derivative of the present invention can improve electrochemical stability of a compound into which the carbazole derivative is introduced as a substituent. In addition, the improvement in electrochemical stability can improve reliability, as a material for a light emitting element, of the compound into which the carbazole derivative is introduced as a substituent.

### EXAMPLE 4

This Example describes a manufacturing method and properties of a light emitting element which includes a light emitting layer using CzA1PA as a light emitting material and 9-[4-(N-carbazolyl)]phenyl-10-phenylathracene (abbr.: CzPA) as a host.

The light emitting element is formed over a glass substrate. First, an ITSO film was formed as a first electrode with a thickness of 110 nm. The ITSO film was formed by a sputtering method. Subsequently, the shape of the first electrode was processed into a square of 2 mm×2 mm by etching. The surface of the substrate was cleaned with a porous resin (typically, made of PVA (polyvinyl alcohol), nylon, or the like) before forming the light emitting element over the first electrode. Further, heat treatment was performed at 200° C. for one hour, and then, UV ozonation was performed for 370 seconds.

Next, a hole injection layer was formed with a thickness of 50 nm. As a material, 4,4′-bis[N-(4-(N,N-di-m-tolylamino)phenyl)-N-phenylamino]biphenyl (hereinafter referred to as DNTPD) was used. Subsequently, an NPB film was formed as a hole transport layer with a thickness of 10 nm. Over these stacked films, a co-evaporated film of CzPA and CzA1PA was formed with a thickness of 40 nm as a light emitting layer. A weight ratio of CzPA to CzA1PA was 1:0.10. Furthermore, an Alq₃ film was formed with a thickness of 10 nm or 20 nm as an electron transport layer, and a co-evaporated film of Alq₃ and lithium (Alq₃:Li=1:0.01) with a thickness of 10 nm or a calcium fluoride (CaF₂) film with a thickness of 1 nm was formed as an electron injection layer. Lastly, an Al film was formed with a thickness of 200 nm as a second electrode, thereby completing the element. Note that each of the films from the hole injection layer to the second electrode was formed by a vacuum evaporation method by resistance heating. An element using an Alq₃ film with a thickness of 10 nm as an electron transport layer and a co-evaporated film of Alq₃ and lithium as an electron injection layer is referred to as Element A, and an element using an Alq₃ film with a thickness of 20 nm as an electron transporting layer and a calcium fluoride film as an electron injection layer is referred to as Element B.

Properties of Element A and Element B are shown in Table 1.

[Table 1]

It is found that both of the elements emit light efficiently, and CzPA suitably functions as a host of the light emitting layer and CzA1PA suitably functions as a dopant of the light emitting layer.

In addition, reliability of Element A and Element B was examined. In driving under conditions with an initial luminance of 500 cd/m² and a constant current density, the time it takes for luminance of Element A to decrease by 10% was 62 hours and that of Element B was 80 hours. Note that CzA1PA is a light emitting material which exhibits blue light emission. This result can be said to be a favorable value as a blue light emitting element.

### EXAMPLE 5

This Example describes a manufacturing method and properties of a light emitting element using only CzA1PA as a light emitting layer.

The element was manufactured in a similar manner to Example 4, and a DNTPD film with a thickness of 50 nm was formed as a hole injection layer over a first electrode (using ITSO). Thereover, an NPB film with a thickness of 10 nm was stacked as a hole transport layer. Next, a CzA1PA film was formed with a thickness of 40 nm as a light emitting layer. An Alq₃ film was formed over the light emitting layer with a thickness of 10 nm as an electron transport layer. A co-evaporated film of Alq₃ and lithium (Alq₃:Li=1:0.01) was formed with a thickness of 10 nm as an electron injection layer. Further, an Al film was formed with a thickness of 200 nm as a second electrode. This element is referred to as Element C.

Properties of Element C are shown in Table 2.

[Table 2]

It is found that Element C emits light efficiently, and CzA1PA suitably functions as a light emitting material.

### REFERENCE EXAMPLE

CzPA used in Examples 4 and 5 is a novel substance. A synthesis method thereof is described below.

A synthesis method of CzPA using, as a starting material, 9-(4-bromophenyl)-10-phenylanthracene obtained by [Step 1] in Example 2 is described. A mixture of 1.3 g (3.2 mmol) of 9-(4-bromophenyl)-10-phenylanthracene, 578 mg (3.5 mmol) of carbazole, 50 mg (0.017 mmol) of bis(dibenzylideneacetone)palladium(O), 1.0 mg (0.010 mmol) of t-butoxy sodium, 0.1 mL of tri(t-butylphosphine), and 30 mL of toluene was heated to reflux at 110° C. for 10 hours. After the reaction, the reaction solution was washed with water. After washing, a water layer was extracted with toluene. After the extraction, the water layer as well as an organic layer was washed with a saturated aqueous sodium chloride solution. After washing, the water layer and the organic layer were dried with magnesium sulfate. After natural filtration, the oil obtained by concentrating the filtrate was purified by silica gel chromatography (hexane:toluene=7:3). Subsequently, the oil was recrystallized with dichloromethane and hexane. Then, 1.5 g of aimed CzPA was obtained with a yield of 93%. 5.50 g of the obtained CzPA was subjected to sublimation purification for 20 hours under conditions at 270° C., under a stream of argon (a flow rate of 3.0 mL/min), and under a pressure of 6.7 Pa; as a result, 3.98 g of CzPA could be recovered (recovery percentage: 72%). A synthesis scheme of CzPA from 9-phenyl-10-(4-bromophenyl)anthracene is shown below.

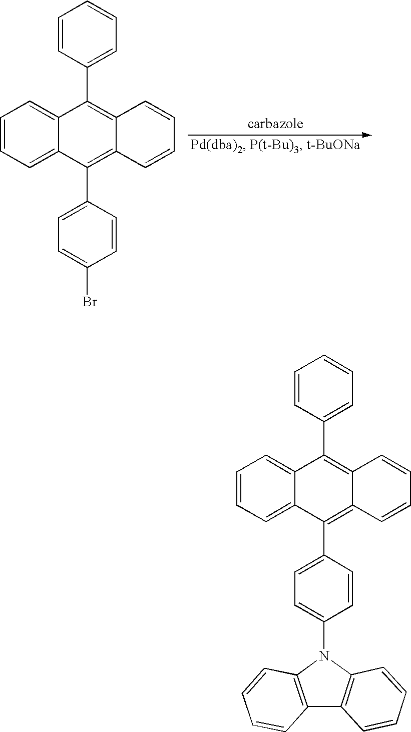

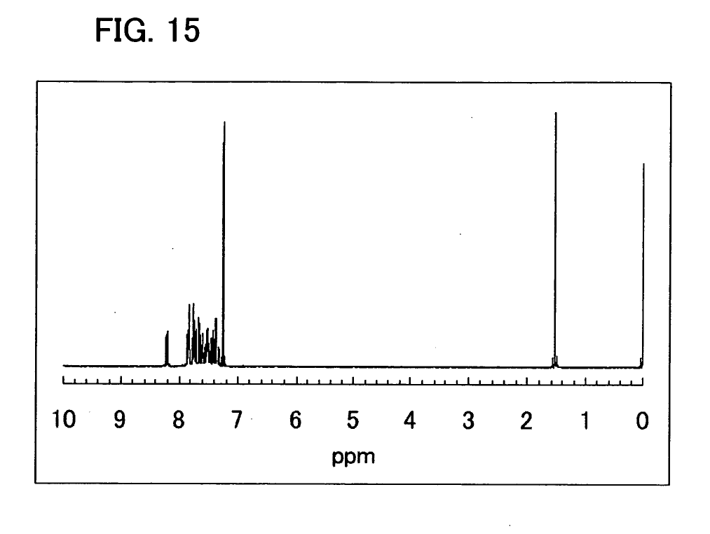

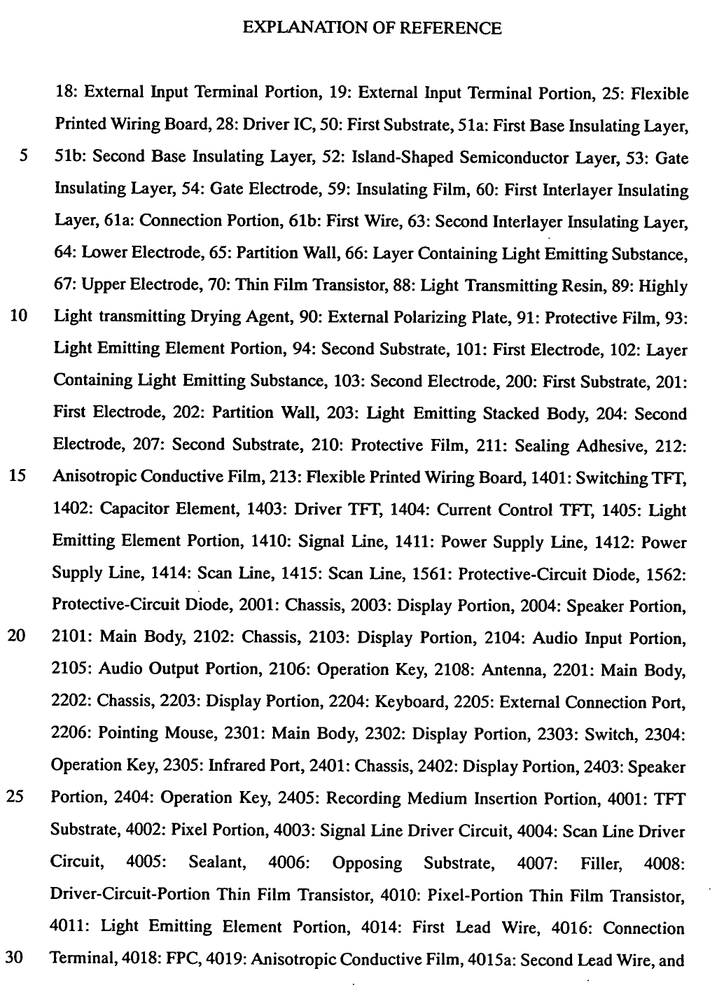

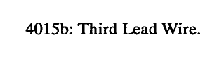

NMR data of the obtained CzPA are shown below. ¹H NMR (300 MHz, CDCl₃); δ=8.22 (d,J=7.8 Hz, 2H), 7.86-7.82 (m, 3H), 7.61-7.36 (m, 20H). In addition, a ¹H NMR chart is shown in FIG. 15.

CzPA was a light yellow powdered solid. A thermogravimetry-differential thermal analysis (TG-DTA) of CzPA was performed. A thermo-gravimetric/differential thermal analyzer (TG/DTA SCC/320, manufactured by Seiko Instruments Inc.) was used for the measurement. Then, thermophysical properties were evaluated at a temperature rising rate of 10° C./min under a nitrogen atmosphere. As a result, from the relationship between gravity and temperature (thermogravimetry), the temperature at which the gravity becomes 95% or less of the gravity at the start of the measurement, was 348° C. under normal pressure. Furthermore, a glass transition temperature and a melting point of CzPA were examined using a differential scanning calorimeter (Pyris 1 DSC, manufactured by Perkin Elmer Co., Ltd.). Accordingly, it was found that the transition temperature was 125° C. and the melting point was 313° C., and CzPA was also thermally stable.

This application is based on Japanese Patent Application serial no. 2005-252308 filed in Japan Patent Office on Aug. 31, 2005, the contents of which are hereby incorporated by reference.

1. A carbazole derivative represented by the following general formula (1), 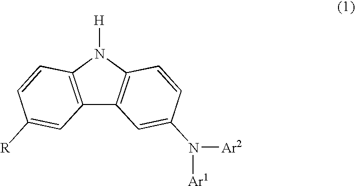
wherein each of Ar¹ and Ar² in the formula represents an aryl group having 6 to 14 carbon atoms, and
R in the formula represents hydrogen or an alkyl group having 1 to 4 carbon atoms.

2. A carbazole derivative represented by the following structural formula (2).

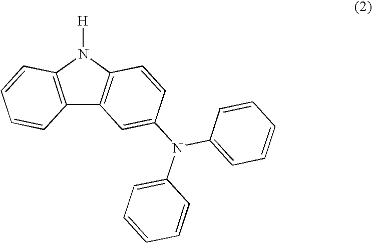

3. A material for a light emitting element into which a carbazole site represented by the following general formula (3) is introduced as a substituent, 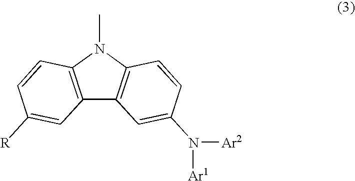
wherein each of Ar¹ and Ar² in the formula represents an aryl group having 6 to 14 carbon atoms, and
R in the formula represents hydrogen or an alkyl group having 1 to 4 carbon atoms.

4. A material for a light emitting element into which a carbazole site represented by the following structural formula (4) is introduced as a substituent.

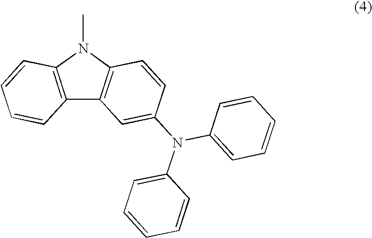

5. A material for a light emitting element, represented by the following general formula (5), 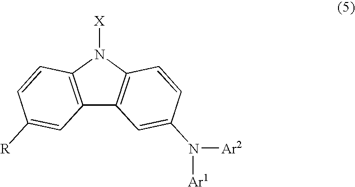
wherein each of Ar¹ and Ar² in the formula represents an aryl group having 6 to 14 carbon atoms,
R in the formula represents hydrogen or an alkyl group having 1 to 4 carbon atoms, and
X in the formula represents a light emitting unit.

6. A material for a light emitting element, represented by the following structural formula (6), 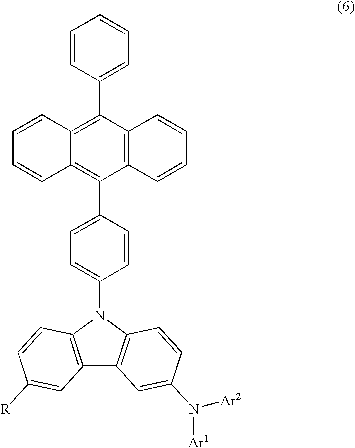
wherein each of A¹ and Ar² in the formula represents an aryl group having 6 to 14 carbon atoms, and
R in the formula represents hydrogen or an alkyl group having 1 to 4 carbon atoms.

7. A light emitting element containing the material for a light emitting element according to claim 3.

8. A light emitting element containing the material for a light emitting element according to claim 4.

9. A light emitting element containing the material for a light emitting element according to claim 5.

10. A light emitting element containing the material for a light emitting element according to claim 6.

11. A light emitting device comprising:
the light emitting element according to claim 7; and
a control circuit which controls light emission of the light emitting element.

12. A light emitting device comprising:
the light emitting element according to claim 8; and
a control circuit which controls light emission of the light emitting element.

13. A light emitting device comprising:
the light emitting element according to claim 9; and
a control circuit which controls light emission of the light emitting element.

14. A light emitting device comprising:
the light emitting element according to claim 10; and
a control circuit which controls light emission of the light emitting element.

15. An electronic device comprising:
a display portion having the light emitting element according to claim 7; and
a control circuit which controls the light emitting element.

16. An electronic device comprising:
a display portion having the light emitting element according to claim 8; and
a control circuit which controls the light emitting element.

17. An electronic device comprising:
a display portion having the light emitting element according to claim 9; and
a control circuit which controls the light emitting element.

18. An electronic device comprising:
a display portion having the light emitting element according to claim 10; and
a control circuit which controls the light emitting element.
